(19) United States
(12) Patent Application Publication
(10) Pub. No.: US 2026/0319370 A1
(43) Pub. Date: Oct. 15, 2026

(54) OXIDATIVE SURFACE TREATMENTS ON UNDERLAYERS TO REDUCE THE DOSE TO SIZE OF EUV PHOTORESISTS

(71) Applicant: Lam Research Corporation, Fremont, CA (US)

(72) Inventors: Joshua James DeMuth, Beaverton, OR (US); Jun Xue, Fremont, CA (US); Samantha S.H. Tan, Newark, CA (US); Nayan Chakravarty, Fremont, CA (US); Jialing Yang, Sherwood, OR (US); Seongjun Heo, Dublin, CA (US); Ge Yuan, San Jose, CA (US); David Alcazar, Palo Alto, CA (US); Faith Anika Hong, Milpitas, CA (US)

(21) Appl. No.: 19/482,119

(22) PCT Filed: May 6, 2024
(86) PCT No.: PCT/US2024/028046

§ 371 Date: Nov. 6, 2025

Related U.S. Application Data
(60) Provisional application No. 63/501,078, filed on May 9, 2023.

(51) Int. Cl. G03F 7/11; G03F 7/00; G03F 7/004; G03F 7/16

(52) U.S. Cl. CPC G03F 7/11; G03F 7/0043; G03F 7/16; G03F 7/70033; G03F 7/70808

(57) ABSTRACT

Provided are oxidative surface treatments for photoresist underlayers to enhance their capability to withstand oxidative stress during the photolithography process. Photoresist underlayers stabilized in this manner can improve the efficiency of the EUV photolithography process and facilitate high volume manufacturing, through reduction of variation in critical dimensions and/or reduction in dose to size. The oxidative surface treatments include dry treatment, heating, wet treatment and oxygen plasma treatment. Suitable underlayer candidates for the treatment are silicon and/or carbon containing underlayers such as amorphous carbon underlayers for use with metal oxide-containing photoresists.

### CROSS-REFERENCES

A PCT Request Form is filed concurrently with this specification as part of the present application. Each application that the present application claims benefit of or priority to as identified in the concurrently filed PCT Request Form is incorporated by reference herein in their entireties and for all purposes.

### FIELD

This disclosure relates generally to the field of semiconductor processing, and in particular to extreme ultraviolet (EUV) photoresist (PR) lithography techniques and materials.

### BACKGROUND

As semiconductor fabrication continues to advance, feature sizes continue to shrink, and new processing methods are needed. One area where advances are being made is in the context of patterning, for example using photoresist materials that are sensitive to lithographic radiation.

Photolithography is used extensively in the fabrication of integrated circuits (IC's). A photoresist (PR) is a radiation sensitive film that captures photons emitted from a masked radiation source to print a desired pattern in the film. Extreme ultraviolet (EUV) photolithography is an emerging technology that makes use of a ~13.5 nm source to print small patterns used in the fabrication of IC's with single or multiple passes. One of the main factors preventing the widespread adoption of EUV technology is the need for more sensitive EUV photoresists. Increasing the sensitivity of EUV photoresists increases the throughput of scanners and reduces critical stochastic defects at low dose regimes.

Dose to size (DtS) is the dose needed to yield the targeted feature size (defined by mask). The lower the DtS the faster the wafer throughput on the scanner (EUV litho tool). Therefore, processes which can reduce dose to size are desirable. Certain photoresist underlayers have been shown to reduce DtS and pattern edge roughness. However, one issue with underlayers used in EUV lithography is their stability in air which can impact their ability to provide consistent lithographic results due to this “oxidative aging”. This introduces a Qtime or aging effect that is problematic for high volume manufacturing. Therefore, a process that can stabilize the underlayers against oxidative aging is desirable.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided are oxidative surface treatments for photoresist underlayers in order to stabilize them against oxidative aging effects during photolithography processing. Photoresist underlayers stabilized in this manner can improve the efficiency of the EUV photolithography process and facilitate high volume manufacturing, through reduction of variation in critical dimensions and/or reduction in dose to size. The oxidative surface treatments include dry treatment, heating, wet treatment and oxygen plasma treatment. Suitable underlayer candidates for the treatment are silicon and/or carbon containing underlayers such as amorphous carbon underlayers for use with metal oxide-containing photoresists.

Accordingly, in a first aspect, the present disclosure encompasses a method for forming a patterning structure. In some embodiments, the method includes providing a substrate; depositing an underlayer on the substrate having a top surface; oxidatively treating the top surface of the underlayer to form a stabilized underlayer; forming a film of a radiation-sensitive imaging layer comprising a metal oxide-containing photoresist on the stabilized underlayer; exposing the film to extreme ultraviolet radiation to make a film having exposed regions and unexposed regions and to activate the stabilized underlayer to generate reactive species, wherein the reactive species generated in the stabilized underlayer preferentially interact with the exposed regions to form exposed cross-linked regions; performing a post-exposure bake and developing the film having exposed cross-linked regions and unexposed regions; and where the stabilized underlayer is oxidative age-resistant and provides reduced dose to size.

In some embodiments, oxidatively treating the underlayer is a dry treatment, heating, a wet treatment, an oxygen plasma treatment or a combination thereof.

In some embodiments, the heating is performed at a temperature of about 50° C. to about 180° C. while exposing the underlayer to an oxygen-containing gas.

In some embodiments, the dry treatment comprises a treatment with nitrous oxide gas, ozone gas, water vapor, hydrogen peroxide vapor or a combination thereof.

In some embodiments, the wet treatment comprises treatment with water, treatment with hydrogen peroxide in water or treatment with ozone in water.

In some embodiments, depositing the underlayer on the substrate and oxidatively treating the top surface of the underlayer are performed simultaneously.

In some embodiments, oxidatively treating the top surface of the underlayer and forming a film of a radiation-sensitive imaging layer on the underlayer are performed simultaneously.

In some embodiments, the underlayer is a carbon-containing underlayer or a silicon-containing underlayer.

In some embodiments, the carbon-containing underlayer is a carbon-containing doped film or an amorphous carbon underlayer.

In some embodiments, the carbon-containing doped film is hydrogenated carbon doped with oxygen, silicon, nitrogen, tungsten, boron, iodine, chlorine or a combination thereof.

In some embodiments, the carbon-containing doped film is doped with a halogen, a metal, an organometallic complex, hydrogen, oxygen or a combination thereof.

In some embodiments, the metal is gold, platinum, palladium, osmium, iridium, titanium, ruthenium, rhodium, silver, tungsten or a combination thereof.

In some embodiments, the organometallic complex is an organometallic complex with oxidizable metal-carbon bonds.

In some embodiments, the organometallic complex with oxidizable metal-carbon bonds is organoruthenium, organoplatinum, organopalladium, organoiridium, organogold, organoosmium or organorhodium.

In a second aspect, the present disclosure encompasses a method for preparing a substrate for extreme ultraviolet photolithography. In some embodiments, the method includes providing a substrate; depositing an underlayer on the substrate having a top surface; and oxidatively treating the top surface of the underlayer to form a stabilized underlayer, where the stabilized underlayer is oxidative age-resistant and provides reduced dose to size.

In some embodiments, oxidatively treating the underlayer includes a dry treatment, heating, a wet treatment, an oxygen plasma treatment or a combination thereof.

In some embodiments, the heating is performed at a temperature of about 50° C. to about 180° C. while exposing the underlayer to an oxygen-containing gas.

In some embodiments, the dry treatment includes a treatment with nitrous oxide gas, ozone gas, water vapor, hydrogen peroxide vapor or a combination thereof.

In some embodiments, the wet treatment includes treatment with water, treatment with hydrogen peroxide in water or treatment with ozone in water.

In some embodiments, depositing the underlayer on the substrate and oxidatively treating the top surface of the underlayer are performed simultaneously.

In some embodiments, the underlayer is a carbon-containing underlayer or a silicon-containing underlayer.

In some embodiments, the carbon-containing underlayer is a carbon-containing doped film or an amorphous carbon underlayer.

In some embodiments, the carbon-containing doped film is hydrogenated carbon doped with oxygen, silicon, nitrogen, tungsten, boron, iodine, chlorine or a combination thereof.

In some embodiments, the carbon-containing doped film is doped with a halogen, a metal, an organometallic complex, hydrogen, oxygen or a combination thereof.

In some embodiments, the metal is gold, platinum, palladium, osmium, iridium, titanium, ruthenium, rhodium, silver, tungsten or a combination thereof.

In some embodiments, the organometallic complex is an organometallic complex with oxidizable metal-carbon bonds.

In some embodiments, the organometallic complex with oxidizable metal-carbon bonds is organoruthenium, organoplatinum, organopalladium, organoiridium, organogold, organoosmium or organorhodium.

In a third aspect, the present disclosure encompasses an apparatus for treating an underlayer. In some embodiments, the apparatus includes a process chamber having a substrate support; a process gas source connected with the process chamber and flow-control hardware; an underlayer oxidative treatment module operatively connected to the process chamber; and an underlayer oxidative treatment module controller having a processor and a memory, where the processer and the memory are communicatively connected with one another, the processor is at least operatively connected with the flow-control hardware, and the memory stores computer-executable instructions for causing oxidative treatment of the underlayer to form a stabilized underlayer, wherein the stabilized underlayer is oxidative age-resistant and provides reduced dose to size.

In some embodiments, the underlayer oxidative treatment module includes an ampoule assembly connected to a vaporizer and an ozone generator; a plasma generator; a heater; or a combination thereof.

These and other aspects are described further below with reference to the drawings.

### BRIEF DESCRIPTION OF THE DRAWINGS

FIG. 1 presents a process flow diagram for a non-limiting EUV photolithographic method in accordance with certain disclosed embodiments.

FIG. 2 presents a process flow diagram for a non-limiting method for preparing a substrate for EUV photolithography in accordance with certain disclosed embodiments.

FIG. 3A-3C present schematic diagrams of example patterning structures. Provided are (A-C) stages in the fabrication of an example patterning structure in accordance with certain disclosed embodiments.

FIG. 4A is an FTIR spectrum of an underlayer recorded over time to illustrate aging of an untreated underlayer.

FIG. 4B is a graph of the integrated intensities of peaks recorded over time to illustrate aging of an untreated underlayer.

FIG. 5 is a graph of an x-ray photoelectron spectroscopic (XPS) aging study of an underlayer in the presence or absence of a wet oxidative pretreatment in accordance with certain disclosed embodiments.

FIG. 6 is a graph of an x-ray photoelectron spectroscopic aging study of a dry oxidative pretreatment in accordance with certain disclosed embodiments.

FIG. 7 is an illustration of the interactions of exposed and unexposed photoresist over an amorphous carbon underlayer in the presence of an oxidizing agent in accordance with certain disclosed embodiments.

FIG. 8 presents a schematic illustration of an embodiment of a process station for dry development in accordance with certain disclosed embodiments.

FIG. 9 presents a schematic illustration of an embodiment of a multi-station processing tool in accordance with certain disclosed embodiments.

FIG. 10 presents a schematic illustration of an embodiment of an inductively coupled plasma apparatus in accordance with certain disclosed embodiments.

FIG. 11 presents a schematic illustration of an embodiment of a semiconductor process cluster tool architecture in accordance with certain disclosed embodiments.

FIG. 12 depicts a cross-sectional schematic view of an example of a dry deposition apparatus in accordance with certain disclosed embodiments.

FIG. 13 depicts detail side section and plan views of a portion of a top plate, substrate, and edge ring in accordance with certain disclosed embodiments.

FIG. 14 presents a schematic illustration of an embodiment of a dry treatment process apparatus in accordance with certain disclosed embodiments.

FIG. 15 depicts a cross-sectional side view of an example apparatus for performing the methods in accordance with disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### Definitions

As used herein, the phrase “at least one of A, B, and C” should be construed to mean a logical (A or B or C), using a non-exclusive logical “or”, and should not be construed to mean “at least one of A, at least one of B and at least one of C”.

By “deposition” or “vapor deposition” is meant a process in which a layer (e.g., a metal) is formed on one or more surfaces of a substrate from vaporized precursor composition(s), for example in the case of a deposited metal layer, including one or more metal containing compounds. The precursor compositions are vaporized and directed to and/or contacted with one or more surfaces of a substrate (i.e., semiconductor substrate or semiconductor assembly) placed in a deposition chamber. Typically the substrate is heated. These precursor compositions form a non-volatile, thin, uniform layer on the surface(s) of the substrate. One operation of the method is one cycle, and the process can be repeated for as many cycles necessary to obtain the desired layer thickness.

For the purposes of this disclosure, “metal” used in this context should be understood to mean conductor with a maximum resistivity of 500 micro Ohm cm, including metals and conductive metal salts, in particular conductive metal nitrides, e.g., TiN.

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like. The term “semiconductor substrate” or “substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The following detailed description assumes the disclosed implementations are implemented on a semiconductor wafer, such as on a 200 mm, 300 mm, or 450 mm semiconductor wafer. However, the disclosed implementations are not so limited. The work piece may be of various shapes, sizes, and materials. In addition to semiconductor wafers, other work pieces that may take advantage of the disclosed implementations include various articles such as printed circuit boards and the like.

“Silicon oxide” is referred to herein as including chemical compounds including silicon and oxygen atoms, including any and all stoichiometric possibilities for SiₓO_{y}, including integer values of x and y and non-integer values of x and y. For example, “silicon oxide” includes compounds having the formula SiOₙ, where 1≤n≤2, where n can be an integer or non-integer values. “Silicon oxide” can include sub-stoichiometric compounds such as SiO_{1.8}. “Silicon oxide” also includes silicon dioxide (SiO₂) and silicon monoxide (SiO). “Silicon oxide” also includes both natural and synthetic variations and also includes any and all crystalline and molecular structures, including tetrahedral coordination of oxygen atoms surrounding a central silicon atom. “Silicon oxide” also includes amorphous silicon oxide and silicates.

The term “flow control hardware” generally represents components configured to place one or more chemical sources in fluid connection with a processing chamber. Flow control hardware can comprise one or more mass flow controllers and/or valves, for example. Example chemical sources include dielectric film precursor sources, halogen-containing precursor sources, reactant gas sources, and inert gas sources.

The term “forming a gas mixture” generally represents either of or both of mixing a plurality of gases before introducing the plurality of gases into the processing chamber, or mixing a plurality of gases in the processing chamber.

The term “inert gas” generally represents a gas phase material that does not react with other chemicals in a processing chamber during substrate processing. Example inert gases include helium (He), neon (Ne), argon (Ar), krypton (Kr), and xenon (Xe), as well as nitrogen (N₂) in some processes.

The term “plasma” generally represents a gas comprising cations, free radicals and free electrons. The term “in-situ plasma” generally represents a plasma formed at a processing station in a processing chamber. The term “remote plasma” generally represents a plasma formed at a location away from a processing station in a processing chamber.

The term “plasma generator” generally represents a combination of components that can be used to form a plasma. Example components include a radiofrequency power source, an impedance matching network, and one or more electrodes.

The term “precursor” generally represents a chemical species that adsorbs to a substrate surface in an ALD process. The precursor is reacted with a reactant to convert the adsorbed precursor to a film layer.

The term “processing chamber” or “process chamber” generally represents an enclosure in which chemical and/or physical processes are performed on substrates. The pressure, substrate temperature and atmospheric composition within a processing chamber can be controllable to perform the chemical and/or physical processes.

The term “processing tool” may generally represent a machine comprising a processing chamber and other hardware configured to enable processing to be carried out in the processing chamber.

The term “processing station” generally represents a location in a processing chamber at which a substrate is positioned during processing.

The term “reactant” generally represents a chemical species that reacts with a precursor adsorbed to a substrate surface to form a film layer in an ALD process. A reaction between a reactant and a precursor can be facilitated by thermal energy and/or a plasma in various processes.

By “dose” is meant the amount of radiation provided to a semiconductor substrate to induce chemical changes in a radiation-sensitive layer during a photolithography operation.

By “hardmask” is meant a material that acts as a mask during an etching operation, and which is not a soft mask material such as conventional soft organic polymer resists.

By “patterning structure” is meant a partially fabricated semiconductor device intended for use in photolithography.

By “radiation-sensitive imaging layer” is meant a layer of material that is susceptible to change upon exposure to radiation, such as during a photolithography operation.

By “underlayer” is meant a layer positioned between a radiation-sensitive imaging layer and a hardmask layer, and which includes a labile species as described herein.

As used herein, “film” refers to a layer extending in a direction perpendicular to a thickness direction to cover an entire target or concerned surface, or simply a layer covering a target or concerned surface. As used herein, “layer” refers to a structure having a certain thickness formed on a surface. A film or layer may be constituted by a discrete single film or layer having certain characteristics or multiple films or layers, and a boundary between adjacent films or layers may or may not be clear and may or may not be established based on physical, chemical and/or any other characteristics, formation processes or sequences, and/or functions or purposes of the adjacent films or layers.

As used herein, the phrase “configured to” indicates that the referenced structure has one or more features that allow the function to be performed. Examples of such features include physical and/or chemical properties such as dimensions, composition, porosity, etc.

As used herein, the terms “top,” “bottom,” “upper,” “lower,” “above,” and “below” are used to provide a relative relationship between structures. The use of these terms does not indicate or require that a particular structure must be located at a particular location in the apparatus.

As used herein, the term “about” is understood to account for minor increases and/or decreases beyond a recited value, which changes do not significantly impact the desired function of the parameter beyond the recited value(s). In some cases, “about” encompasses +/−10% of any recited value. As used herein, this term modifies any recited value, range of values, or endpoints of one or more ranges.

### Introduction & Context

Extreme ultraviolet (EUV) lithography—typically at a wavelength of 13.5 nm—is considered as the next enabling technology for lithographic patterning. However, a number of technological stumbling blocks have delayed the widespread introduction and implementation of this technique. EUV photoresist (PR) is one of the roadblocks.

Traditional chemically amplified resist (CAR) provides a cost-effective approach. But organic polymer CARs generate higher line edge roughness (LER) and line width roughness (LWR), and have sensitivity and resolution limitations due to random fluctuation of the use of polymer. Recent research and development efforts have focused on new EUV inorganic photoresist platform development. Such systems offer several advantages compared to a polymer-based CAR system. These inorganic photoresists are generally based on metal oxides, including metal hydroxide oxides. The small metal oxide molecule size enhances ultimate resolution of the patterning step, and metal oxide photoresists generally show higher etch resistance than CAR, which can reduce PR thickness to reduce structure aspect ratio.

However, there are various challenges associated with inorganic PR, as well. Spin-On-Carbon (SOC) hardmask materials are often used in hardmask film stacks to which EUV PRs are applied for patterning. But SOCs have a soft carbon (C)-rich film with poor etch resistance and poor LWR. Common hardmask materials such as silicon oxide (e.g., silicon dioxide, SiO₂), silicon nitride, and ashable hardmasks (AHMs) can be used directly under PR for better etch selectivity and good LER and LWR. But delamination between EUV PR and hardmask material, particularly after wet development of the EUV-exposed PR, is a persistent problem. And only about twenty percent of the EUV photons are absorbed by a typical PR, meaning that a large amount of primary and secondary electrons will often be created in a PR underlayer. Dose to Size (DtS) data have shown that there is higher dose required for EUV inorganic PR disposed directly on a common hardmask material than for EUV inorganic PR on SOC for resolving the same line critical dimension.

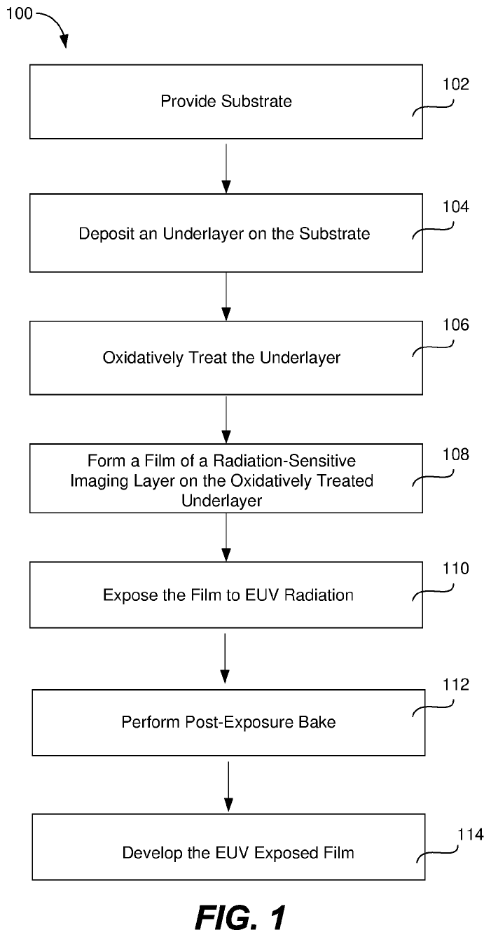

FIG. 1 schematically shows a non-limiting process 100 for forming a patterning structure. As described herein, a thin underlayer film disposed directly under the EUV inorganic PR which is stabilized by an oxidative treatment enables a film stack EUV inorganic PR having improved performance. In operation 102, a substrate as defined above is provided to a process chamber. In some embodiments, the substrate is an amorphous hardmask such as an amorphous carbon hardmask grown at 350° C. and 1 Torr.

The substrate may be, for example, a hardmask, a film, a stack, a partially fabricated semiconductor device film stack, etc., fabricated in any suitable way. In some embodiments, the substrate may include a hardmask disposed on a work piece, such as the partially fabricated semiconductor device film stack. The hardmask, on the uppermost layer of the film stack, may have a variety of compositions, such as SiO₂, silicon nitride, an ashable hardmask material, and may be formed by chemical vapor deposition, for example PECVD. Ashable hardmasks composed of amorphous carbon films are desirable in some implementations. Amorphous carbon films in this context may be undoped or doped with boron (B) or tungsten (W), for example. Suitable amorphous carbon films may have a composition including about 50 to 80 atomic % carbon (C), 10 to 20 atomic % hydrogen (H), and 5 to 40 atomic % B or W dopant, for example.

Yet other substrates can be employed. For instance, the substrate can be or include an amorphous hydrogenated carbon, silicon oxide, silicon nitride, silicon oxynitride, silicon carbide, silicon boronitride, amorphous silicon, polysilicon, or a combination of any described herein, in any form (e.g., a bulk film, a thin film, another film, a stack, etc.).

In operation 104, an underlayer is deposited over the substrate. Useful underlayers have chemically labile or activatable moieties. The underlayer may be carbon-containing or silicon-containing in some embodiments. The activatable moieties may be constituents of the underlayer, added to the underlayer as dopants, or be both constituents of the underlayer and stem from dopants.

Sources of the carbon-containing films can include, but are not limited to, methane, acetylene, ethylene, propylene, propyne, allene, cyclopropene, butane, cyclohexane, benzene and toluene.

In some embodiments, when the underlayer is a carbon-containing underlayer, it may have certain types of bonds which are susceptible to cleavage under appropriate conditions, which may include heat, an oxidizing gas or a combination of heat and oxidizing gas. Some examples of activatable C—H bonds include, but are not limited to, allylic C—H, ether alpha C—H, vinyl C—H, C—H bonds alpha to a ketone group, C—H bonds alpha to an aldehyde or on the carbonyl carbon, tertiary C—H and benzylic C—H's.

For such carbon-containing underlayers, the synergistic action of an oxidizing gas causes release of reactive moieties. The moieties may be reactive species comprise peroxy radicals, hydroperoxy radicals, oxy radicals, hydroxy radicals, hydrogen radicals, formate radicals, iodine radicals, carbon dioxide, carbon monoxide, water, iodine, hydrogen iodide, formate anions, superoxide anions, or a combination thereof.

Without wishing to be bound by theory, the reactive species (once released from the bake sensitive underlayer having activatable moieties) may diffuse into the imaging layer and cross-link the imaging layer material. This cross-linking results in reduction of dose to size.

When the carbon-containing underlayer is doped with a halide for example, an oxidizing gas may be unnecessary, as heat alone is sufficient to break a C—X bond. For such underlayers, reactive species can include halogen radicals or anions.

Sources of iodine dopants for the carbon-containing underlayers include the precursors HI, CH₂I₂, CH₃I, ICH₂CH₂I, C₂H₄I, CF₃I or ICF₂CF₂I in some embodiments.

Sources of bromine dopants for the carbon-containing underlayers include the precursors HBr, CH₂Br₂, CH₃Br, BrCH₂CH₂Br, C₂H₄Br, CF₃Br, or BrCF₂CF₂Br in some embodiments.

Sources of chlorine dopants for the carbon-containing underlayers include the precursors HCl, CH₂Cl₂, CH₃Cl, ClCH₂CH₂Cl, C₂H₄Cl, CF₃Cl or ClCF₂CF₂Cl in some embodiments.

Sources of fluorine dopants for the carbon-containing underlayers include the precursors HF, CH₂F₂, CH₃F, CF₄, FCH₂CH₂F, C₂H₄F, CF₃F or C₂F₆ in some embodiments.

Similar to the example of carbon-containing underlayers doped with halides, when the carbon-containing underlayer is doped with a metal or an organometallic complex, an oxidizing gas may be unnecessary, as heat alone may be sufficient to break a C-M bond.

In some embodiments, suitable metals include gold, platinum, palladium, osmium, iridium, titanium, ruthenium, rhodium, silver, tungsten or a combination thereof. Metals may be applied either as a thin layer on the underlayer, or deposited with the underlayer precursor.

In some embodiments, suitable organometallic complexes include those with oxidizable metal-carbon bonds such as organoruthenium, organoplatinum, organopalladium, organoiridium, organogold, organoosmium or organorhodium.

The organometallic complex-doped underlayers may be produced by various techniques. In one embodiment, the underlayer is first deposited on a substrate. Then the underlayer is soaked in an organometallic complex dissolved in solution; and optionally heated. As a result of the soaking, organometallic complex may be 1) deposited as a thin layer coating the underlayer; 2) dispersed throughout the underlayer; or 3) deposited as a thin layer and dispersed throughout the underlayer.

In some embodiments, solvents which may be utilized to dissolve the organometallic complexes include tetrahydrofuran, n-hexane, acetonitrile, ethanol, isopropyl alcohol or dimethyl sulfoxide. The soak time may be from about 20 seconds to about 5 minutes. During soaking, the solution may optionally be heated to a temperature of from about 25° C. to about 150° C.

Suitable organorhodium complexes include dicarbonyl(pentamethylcyclopentadienyl) rhodium(I) in some embodiments.

Suitable organoosmium complexes include bis(pentamethylcyclopentadienyl)osmium and bis(cyclopentadienyl)osmium.

Suitable organogold complexes include dimethyl(acetylacetonate)gold(III).

Suitable organoiridium complexes include (methylcyclopentadienyl)(1,5-cyclooctadiene)iridium(I) and 1-ethylcyclopentadienyl-1,3-cyclohexadiene iridium (I).

Suitable organopalladium complexes include allyl(cyclopentadienyl)palladium(II).

Suitable organoplatinum complexes include (trimethyl)pentamethylcyclopentadienyl platinum (IV) and trimethyl(methylcyclopentadieny1)platinum (IV).

Suitable organoruthenium complexes include those with cyclopentadienyl, cyclic unsaturated hydrocarbon, alkyl, alkenyl or beta-diketonate ligands.

The underlayer may also be composed of a silicon-containing film. The silicon-containing film may be a silicon oxide. In any embodiment, the silicon-containing film may be doped with a halogen, a metal, carbon, hydrogen or a combination thereof.

The underlayer can be deposited with any useful precursor. For instance, the precursor can include a hydrocarbon precursor having only carbon and hydrogen atoms. In another instance, the precursor can be a heteroatom-containing, hydrocarbon precursor having carbon atoms, hydrogen atoms, and non-carbon heteroatoms. In yet another instance, the precursor can be a dopant precursor (e.g., as described herein).

Of the hydrocarbon precursors, various compounds can be employed. For instance, the hydrocarbon precursor can include aliphatic and aromatic compounds (e.g., alkanes, alkenes, alkynes, benzene, etc.), including substituted forms thereof. By using different hydrocarbon precursors, the type and amount of certain chemical bonds within the underlayer can be modified. For instance, using unsaturated hydrocarbon precursors can provide an underlayer having increased unsaturated bond content (e.g., increased C═C and/or C≡C bond content), increased sp² carbon content, increased sp carbon content, decreased saturated bond content (e.g., decreased C—C bond content), decreased sp³ carbon content, and/or decreased C—H bond content (e.g., as compared to a film formed with an increased amount saturated hydrocarbon precursors or a decreased amount of unsaturated hydrocarbon precursors). The selection of the hydrocarbon precursor can depend on various factors. In one non-limiting instance, a hydrocarbon precursor includes a saturated precursor (e.g., having increased C—H bond content, as compared to C—C, C═C, or C≡C content), which can provide sufficient H atoms.

The underlayer can be deposited in any useful manner. In one instance, deposition includes vapor deposition of a hydrocarbon precursor or a carbon-containing precursor (e.g., any described herein). Deposition can include use of a process gas (e.g., as a plasma or as an inert gas) during deposition, in which non-limiting process gases include carbon monoxide (CO), helium (He), argon (Ar), krypton (Kr), neon (Ne), nitrogen (N₂), and/or hydrogen (H₂).

Deposition conditions include control of precursor flow rate(s), gas flow rate(s), process pressure, temperature (e.g., electrostatic chuck (ESC) temperature), plasma (e.g., TCP) power, bias power, and duty cycle (DC) within the processing chamber. The flow rate of precursor(s) may be between about 1-100 standard cubic centimeter per minute (sccm). The flow rate of gas(es) may be between about 1-1600 sccm. The chamber pressure may be between about 5-1000 mTorr (e.g., 5-800 mTorr, 10-500 mTorr, 10-400 mTorr, 30-500 mTorr, 10-1000 mTorr, or 30-1000 mTorr). The ESC temperature may be between about 0-250° C. (e.g., 0 -50° C. or 10-40° C.). The power used to generate the plasma may be between about 10-3000 W per station (e.g., 100-1000 W, 200-1000W, 200-800 W, or 200-500 W). The RF frequency used to generate the plasma can be between about 0.3-600 MHz (e.g., 13.56 MHz, 60 MHz, 27 MHz, 2 MHz, 400 kHz, or combinations thereof). The RF bias power may be between about 0 -1000 W using a pulsed plasma or a continuous wave (CW) plasma. The processing chamber can be an ICP chamber or a CCP chamber. In some embodiments of the ICP chamber, the frequency of both the top ICP generator and the bias generator is 13.5 MHz. Depending on the underlayer, in some embodiments, the pressure can be about 10-400 mTorr, and the TCP power can be about 200-500 W.

For example, the photoresist underlayer may have a thickness of about 2 to 40 nm, e.g., 2, 3, 4, 5, 6, 7, 8, 9, 10, 15 or 40 nm, and may optionally include about 0 -30 atomic % O and/or about 20-50 atomic % hydrogen (H), 0-16 atomic % of a halogen such as iodine, fluorine, bromine or chlorine and/or 30-70 atomic % C. Other underlayer properties are described herein.

In some implementations, the underlayer may be vapor deposited on the substrate by PECVD or ALD using a hydrocarbon precursor, which can be with or without carbon monoxide (CO) and/or carbon dioxide (CO₂). In particular embodiments, vapor deposition includes introducing or delivering a hydrocarbon precursor without CO and without CO₂.

In some implementations, the underlayer may be vapor deposited on the substrate by PECVD or ALD using an oxocarbon precursor that co-reacts with hydrogen (H₂) or a hydrocarbon. In variations on this implementation, the oxocarbon precursor may further co-react with a Si source dopant during the deposition. In particular embodiments, oxocarbon precursors can include CO or CO₂. Without wishing to be limited by mechanism, the use of oxocarbon precursors can include hydroxyl (—OH) groups or other oxygen-containing groups to the underlayer, which can provide a hydrophilic surface or a surface with increased hydrophilicity (as compared to an underlayer lacking such-OH or oxygen-containing groups). In non-limiting examples, a hydrophilic surface can improve adhesion between the underlayer and the PR layer.

In other implementations, the underlayer may be vapor deposited on the substrate by PECVD or ALD using a Si-containing precursor that co-reacts with an oxidizer (e.g., an oxocarbon, an O-containing precursor, CO, or CO₂). In variations on this implementation, the Si-containing precursor further co-reacts with a C source dopant (e.g., a hydrocarbon precursor, as described herein). Non-limiting Si-containing precursors are described herein, such as silanes, halosilanes, aminosilanes, alkoxysilanes, organosilanes, etc.

In some implementations, the underlayer may be vapor deposited on the substrate by PECVD as a termination operation of a vapor deposition on the substrate, for example by adjusting the precursor flows entering the PECVD process chamber to achieve the desired composition of the photoresist underlayer.

In other implementations, underlayer may be vapor deposited on the substrate by PECVD to provide a hydrogenated carbon film. In some embodiments, the film is a low density film (e.g., from 0.7-2.9 g/cm³). In other embodiments, the undoped film (or a film prior to doping) has a density less than about 1.5 g/cm³ or a density of about 0.7-1.4 g/cm³. In yet other embodiments, the doped film has a density of about 0.7-1.4 g/cm³.

The PECVD process can include any useful precursor or combinations of precursors. In one embodiment, the precursor is a hydrocarbon precursor (e.g., any described herein). Optionally, a doped, hydrogenated carbon film is formed by using a heteroatom-containing precursor (e.g., a nitrogen-containing precursor, a tungsten-containing precursor, a boron-containing precursor, and/or an iodine-containing precursor) during the PECVD process.

Deposition of the underlayer can include use of plasma (e.g., as in a PECVD process), including transformer coupled plasma (TCP), inductively coupled plasma (ICP), or capacitively coupled plasma (CCP). In particular embodiments, deposition can use low TCP power (e.g., about 100-1000 W) with minimum bias (e.g., no bias) to provide a low density film. Of course, higher power plasmas can be employed, as described herein. In certain embodiments, generation of plasma (e.g., TCP or ICP) can be controlled by power, which is in a continuous wave (CW) mode.

Deposition (e.g., with TCP or ICP power in CW mode) can include an applied bias (regardless of frequency) that is pulsed (e.g., in the range of about 1 Hz to about 10 kHz, such as 10-2000 Hz) with a duty cycle between about 1% and 99%. Additional pulsing frequencies and duty cycles are described herein. In some embodiments, the applied pulsed bias can be provided to control ion energy. Non-limiting applied pulsed bias power can be from about 10-1000 W, as well as other ranges described herein.

In yet other embodiments, deposition can include an applied CW bias. CW bias may also be used to control ion energy. In some embodiments, the applied CW bias power can be from 10-1000 W (e.g., 10-500 W, 10-400 W, as well as other ranges described herein).

Yet other conditions (e.g., useful for a low density film) includes use of certain pressure conditions (e.g., such as 5-1000 millitorr (mTorr), including 10-1000 mTorr, 10-500 mTorr, or 10-400 mTorr) and certain temperature conditions (e.g., such as about 0 -100° C., including 0-50° C. and 10-40° C.).

Pulsed or continuous bias can be employed to fine tune properties of the film. In one embodiment, pulsed bias can provide a higher density film, as compared to a low density film prepared with 0 W of bias power. Such higher density films can, in some instances, provide increased etch resistance, as compared to the low density film. In other instances, such higher density films can provide reduced undercut, as compared to a low density film prepared with 0 W of bias power. Additional plasma conditions and processes are also described herein.

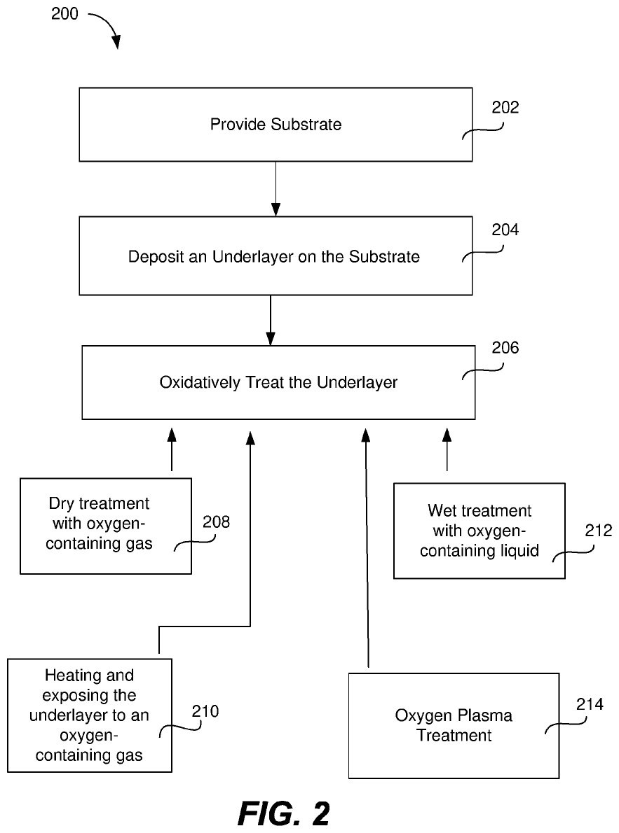

In operation 106, the underlayer deposited in operation 104 is oxidatively treated. Operations 104 and 106 may occur simultaneously in certain embodiments. Oxidative treatments for the underlayer are described in greater detail with reference to FIG. 2 below.

In operation 108, a film of a radiation-sensitive layer is deposited over the oxidatively treated underlayer. In some embodiments, operations 106 and 108 may be performed simultaneously.

The patterning structures (or films) herein can include an imaging layer on a surface of a hardmask or a substrate, as well as an underlayer under the imaging layer. In particular embodiments, the presence of the underlayer provides increased radiation absorptivity and/or patterning performance of the imaging layer.

Generally, photon absorption through a layer is depth dependent. When a homogenous layer or film is exposed to radiation, the lower portion of the layer is exposed to a lower dose of radiation, as compared to the upper portion of that same layer, because fewer photons reach that lower portion. Thus, to ensure sufficient and uniform exposure through the entire depth of a layer, the layer must provide sufficient transmission of the radiation. In particular embodiments, the underlayer described herein provides increased radiation absorption through the imaging layer. Furthermore, in some instances, the underlayer can effectively generate more secondary electrons that can better expose lower portions of the patterning structure.

One or both of the underlayer and the imaging layer can include a high-absorbing element. In one instance, the underlayer and the imaging layer both include a high-absorbing element, such as equal to or greater than 1×10⁷ cm²/mol for EUV absorption. The element in each of the absorbing and imaging layers can be the same or different. In particular embodiments, enhanced adhesion can lower the required radiation dose to provide desired patterned features within the imaging layer and/or the underlayer.

The imaging layer can include any useful resist, such as metal-organic based resists, as described herein. When the photoresist material being employed possesses a significant inorganic component, for example it exhibits a predominately metal oxide framework, the underlayer may advantageously be a carbon-based film. In cases where there are device features present on the substrate to be patterned which create significant topography, another important function of the underlayer can be to overcoat and planarize the existing topography so that the subsequent patterning step may be performed on a flat surface with all areas of the pattern in focus. For such applications, the underlayer (or at least one of multiple underlayers) may be applied using dry deposition or spin-coating techniques. The layer may include various AHM films with carbon-and hydrogen-based compositions, and may be doped with additional elements such as tungsten, boron, nitrogen, or fluorine.

The underlayer and imaging layer, either alone or together, can be considered a film. In some embodiments, the film is a radiation-sensitive film (e.g., an EUV-sensitive film). This film, in turn, can serve as an EUV resist, as further described herein. In particular embodiments, the layer or film can include one or more ligands (e.g., EUV labile ligands) that can be removed, cleaved, or cross-linked by radiation (e.g., EUV or DUV radiation).

Precursors can be used to provide a patternable film that is sensitive to radiation (or a patterning radiation-sensitive film or a photopatternable film). Such radiation can include EUV radiation, DUV radiation, or UV radiation that is provided by irradiating through a patterned mask, thereby being a patterned radiation. The film itself can be altered by being exposed to such radiation, such that the film is radiation-sensitive or photosensitive. In particular embodiments, the precursor is an organometallic compound, which includes at least one metal center.

The precursor can have any useful number and type of ligand(s). In some embodiments, the ligand can be characterized by its ability to react in the presence of a counter-reactant or in the presence of patterned radiation. For instance, the precursor can include a ligand that reacts with a counter-reactant, which can introduce linkages between metal centers (e.g., an —O— linkage).

Yet other exemplary EUV-sensitive materials, as well as processing methods and apparatuses, are described in U.S. Pat. No. 9,996,004; Int'1. Pat. Pub. No. WO 2020/102085; and Int'l. Pat. Pub. No. WO 2019/217749, each of which is incorporated herein by reference in its entirety.

In operation 110, the film is exposed to EUV radiation to develop a pattern. Generally, the EUV exposure causes a change in the chemical composition of the film, creating a contrast in etch selectivity that can be used to remove a portion of the film. Such a contrast can provide a positive tone resist or a negative tone resist.

In operation 112, a post exposure bake is performed. A post exposure bake (PEB) of the exposed film, removes residual moisture or promoting chemical condensation within the film. In another instance, the method can include (e.g., after development) hardening the patterned film, thereby providing a resist mask disposed on a top surface of the substrate. Hardening steps can include any useful process to further crosslink or react the EUV unexposed or exposed areas, such as steps of exposing to plasma (e.g., O₂, Ar, He, or CO₂ plasma), exposing to ultraviolet radiation, annealing (e.g., at a temperature of about 180-240° C.), thermal baking, or combinations thereof that can be useful for a post development baking (PDB) step.

In some embodiments, two or more different temperatures may be utilized with a different bake gas ambient (i.e. a first bake in oxidative gas with heating; and a second bake at a higher temperature than the first bake in an inert gas (i.e. 100% N₂).

The duration of heating is variable and can be optimized for the selected underlayer. In some embodiments, duration may be from about 1 to about 10 minutes. In some embodiments, when two or more different temperatures are utilized, the first temperature may be maintained for a first duration, and the second temperature may be maintained for a second duration. The two durations may be the same length of time or different lengths of time.

In operation 114 the EUV exposed film is developed. In various embodiments of development, the exposed regions are removed (positive tone) or the unexposed regions are removed (negative tone). In various embodiments, these steps may be dry processes and/or wet processes.

In some embodiments, the process includes all dry processes, including dry deposition of the film (e.g., with precursors in vapor form and a counter-reactant that includes water vapor) and dry development of the exposed film. Without wishing to be limited by mechanism, such films can provide a negative tone resist, in which radiation exposed regions provide a non-volatile material and radiation unexposed regions provide a volatile byproduct upon exposure to dry development chemistry (e.g., vapor-based etchant chemistry, such as any described herein). In this way, etchants in the vapor phase can be used to react with the unexposed film to provide volatile byproducts, which can also be removed by in its vapor form.

In other embodiments, a wet process can be employed in one or more operations. Such processes can include dry deposition of the film (e.g., with precursors in vapor form and a counter-reactant that includes water vapor) and wet development of the exposed film (e.g., using any wet developer described herein); as well as wet deposition of the film (e.g., with precursor in a solvent) and dry development of the exposed film; and wet deposition of the film with wet development of the exposed film. Without wishing to be limited by mechanism, such films can provide a positive tone resist, in which radiation exposed regions provide a material (e.g., including metal halide bonds, such as tin halide) that can be dissolved in a solvent and radiation regions provide a material that is more resistant to solvent dissolution.

Any useful type of chemistry can be employed during the depositing, patterning, and/or developing steps. Such steps may be based on dry processes employing chemistry in a gaseous phase or wet processes employing chemistry in a wet phase. Various embodiments include combining all dry operations of film formation by vapor deposition, (EUV) lithographic photopatterning, dry stripping, and dry development. Various other embodiments include dry processing operations described herein advantageously combined with wet processing operations, for example, spin-on EUV photoresists (wet process), may be combined with dry development or other wet or dry processes as described herein. In various embodiments, the wafer clean may be a wet process as described herein, while other processes are dry processes. In yet other embodiments, a wet development process may be used.

Developing the exposed wafer will reveal the pattern that was exposed into the photoresist. The photoresist can be developed using a wet or dry method. For wet development a solvent (such as 2-heptanone, isopropyl alcohol, propylene glycol methyl ether or propylene glycol methyl ether acetate) is dispensed onto the wafer while it may or may not be spinning on a chuck. For the dry development hydrogen halides (i.e HI, HCl, or HBr) are diluted (about 10-100% hydrogen halide) with an inert gas (i.e. He, or Ar) and then flown into the chamber that contains the exposed wafer. Typical pressures range from 100 mT-1 Tor, the chuck temperature ranges from −15-20° C. The time of the dry development can vary from 10 s-350 s.

The method 100 can result in a stabilized underlayer which resists oxidative aging. Such stabilized underlayers may be a factor contributing to high volume manufacturing processes. Moreover, an underlayer stabilized against oxidative aging can reduce variations in critical dimensions. As the underlayer film ages the chemically labile bonds at the surface (i.e. C—H bonds) gradually oxidize in air as the film ages which changes the lithographic performance (e.g. DtS, adhesion, pattern edge roughness) of the underlayer. This is problematic in a production or high-volume manufacturing setting because the consistency of the printed features then depend on the age of the underlayer. This method of stabilizing the underlayer essentially “pre-oxidizes” the film (saturating all of an underlayer's easily oxidizable surface sites) and makes it resistant to further oxidative aging. After this treatment the underlayer is no longer oxidizing as it ages and it improves the consistency of the printed features regardless of the underlayer's age. Additionally, it has been shown that increasing the age of the underlayer can reduce the DtS. Thus by treating the underlayer, it not only improves the reliability of the results but also provides a method to reduce the DtS. The method 100 can provide a dose to size reduction which is reduced by about 25%, by about 15%, by about 10% or by about 5% in comparison to a patterning structure which does not have an oxidatively pre-treated underlayer.

FIG. 2 presents a process flow diagram for a non-limiting method for preparing a substrate for EUV photolithography. The method 200 is a process to treat an underlayer to reduce DtS and improve the consistency of the features printed in the lithography process. In operation 202, a substrate is provided as described above with reference to FIG. 1. In operation 204, an underlayer is deposited as described above with reference to FIG. 1.

In operation 206, the underlayer is oxidatively treated. In certain embodiments, operations 204 and 206 may be performed simultaneously. Operations 208-214 represent techniques for performing the presently disclosed oxidative treatment. One of operations 208-214, or two or more of operations 208-214 may be advantageously employed to oxidatively treat the underlayer.

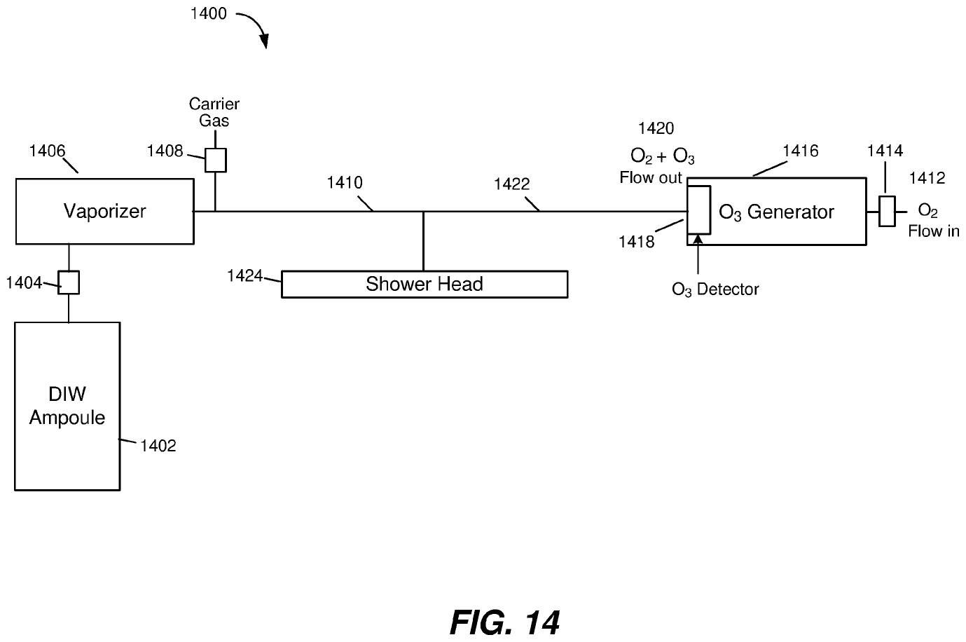

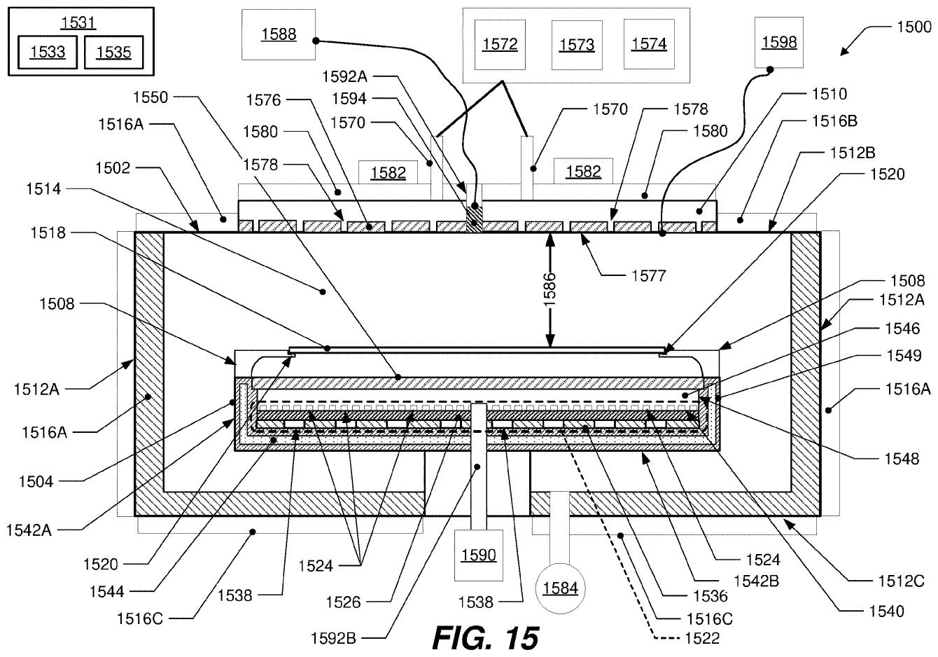

Operation 208 is a dry treatment technique for the oxidative underlayer treatment. As used herein, the phrase “dry treatment” refers to a process which does not include liquid reagents or components. Dry treatments are treatments with appropriate oxidative gases in certain embodiments. Useful oxidative gases include, but are not limited to ozone, water vapor or a combination of ozone and water vapor. An apparatus for dry treatment of the underlayer is described in greater detail in FIGS. 14 and 15 below.

When a combination oxidative gas treatment is utilized such as a combination of ozone and water vapor, the ozone and water vapor can be co-flowed to a process chamber or supplied to a process chamber sequentially. In certain embodiments, the ozone concentration in the combined ozone/water vapor treatment will be from about 1 to about 30%, or from 5 to 15%. The flow rate of the oxidative gases for the dry treatment is from about 100-to about 2500 sccm; the pressure of the process chamber may be from about 50 mTorr to 19 Torr; and the temperature of a process chamber pedestal may be from about 0 to about 100° C. in certain embodiments. The treatment time is from about 3 seconds to about 500 seconds. The oxidative gas treatment (either single component or the combination) may be co-flowed with an inert carrier gas. In certain embodiments, the inert gas is helium, neon, argon, krypton, xenon, radon, nitrogen or a combination thereof.

Operation 210 is a technique to perform the oxidative underlayer treatment by heating, wherein the underlayer is baked in an oxidative ambient (with an oxygen-containing gas) at a pedestal temperature of from about 10° C. to about 200° C., or from 50° C. to about 180° C. for from about 30 seconds to about 5 minutes at a pressure of from about 250-1000 Torr, or about 500-760 Torr. The oxygen-containing gas includes, but is not limited to water vapor, hydrogen peroxide (H₂O₂) vapor, O₂ and nitrous oxide (N₂O). The oxygen-containing gas may be flowed into a process chamber in an inert carrier gas such as nitrogen or argon, where the concentration of the oxygen-containing gas is from 5 to about 40% or from about 5 to about 25%.

Operation 212 is a wet treatment technique for performing the oxidative underlayer treatment. As used herein, the phrase “wet treatment” refers to introduction of or washing with a liquid, such as an oxygen-containing liquid or gas dissolved in deionized water. In some embodiments, the oxygen-containing liquid or gas includes, but is not limited to ozone in water, hydrogen peroxide in water or water. The wet treatment may be applied for from about 3 to about 300 seconds. The oxygen-containing liquid may be from about 0 to about 6 ppm dissolved in water.

Operation 214 is an oxygen plasma treatment technique to perform the oxidative underlayer treatment. An oxygen-containing plasma such as an oxygen plasma or carbon dioxide may be generated at a temperature of from about 10° C. to about 210° C.; a pressure of from about 20 mTorr to 3 Torr; and a power of from about 100 to 500 W. Optionally, the plasma may be pulsed. The plasma may be flowed at a rate of from about 500 to about 5,000 sccm. The plasma may be co-flowed with an inert gas at a flow rate of from about 0 to about 5,000 sccm.

In certain embodiments, the underlayers described above may be utilized in order to prepare patterning structures by methods subjecting them to EUV exposure and a post-exposure bake process. Dose to size reduction and/or increased adhesion are among the advantageous effects of synergistically combining these two steps of the lithographic process. Dose to size reduction an amount of from about 20% to about 60% in comparison to non-bake sensitive underlayers (those lacking activatable moieties).

In certain embodiments, the underlayers described above may be utilized in order to prepare patterning structures by methods subjecting them to EUV exposure, a post-exposure bake, and a development process. In such methods, the reactive species generated form the bake sensitive underlayers (during the PEB) will have a preferential interaction with the EUV exposed regions of the imaging compared to the unexposed regions. This means the reactive species do not indiscriminately interact with exposed and unexposed regions and will contribute to an increased amount of cross-linking in the exposed region of the imaging layer. This yields additional chemical/material contrast in the imaging layer between the unexposed and exposed regions. The advantageous end result of such methods is a decrease in pattern edge roughness and/or a decrease in scumming.

With the underlayers described above, the resulting multilayer (e.g., bilayer) hardmask scheme has comparable or better DtS performance, as compared to EUV inorganic PR directly on a SOC stack. And the underlayer can also serve as an adhesion layer between the EUV inorganic PR and the hardmask, regardless of hardmask film composition, which enables improved etch selectivity and LER/LWR performance. Surfaces other than a hardmask can be employed below the underlayer, in which the underlayer can serve as an adhesion layer between the EUV PR and any useful substrate (e.g., a hardmask, a wafer, a partially fabricated semiconductor device film stack, etc.).

As further described below, suitable underlayer thin films can be deposited by chemical vapor deposition (CVD), plasma enhanced chemical vapor deposition (PECVD), atomic layer deposition (ALD), plasma enhanced atomic layer deposition (PEALD), or other vapor deposition methods (e.g. by sputter deposition, physical vapor deposition (PVD) including PVD co-sputtering). The underlayer deposition process can be implemented in either an etch tool or a deposition tool. In some implementations, it can be integrated as a termination step in a hardmask deposition process. Different film compositions of the underlayer can be chosen depending on the film stack.

It should also be understood that while the present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources; X-ray, which formally includes EUV at the lower energy range of the X-ray range; as well as e-beam, which can cover a wide energy range. Such methods include those where a substrate, having exposed hydroxyl groups, is contacted with a hydrocarbyl-substituted tin capping agent to form a hydrocarbyl-terminated tin oxide (SnOₓ) film as the imaging/PR layer on the surface of the substrate. The specific methods may depend on the particular materials and applications used in the semiconductor substrate and ultimate semiconducting device. Thus, the methods described in this application are merely exemplary of the methods and materials that may be used in present technology.

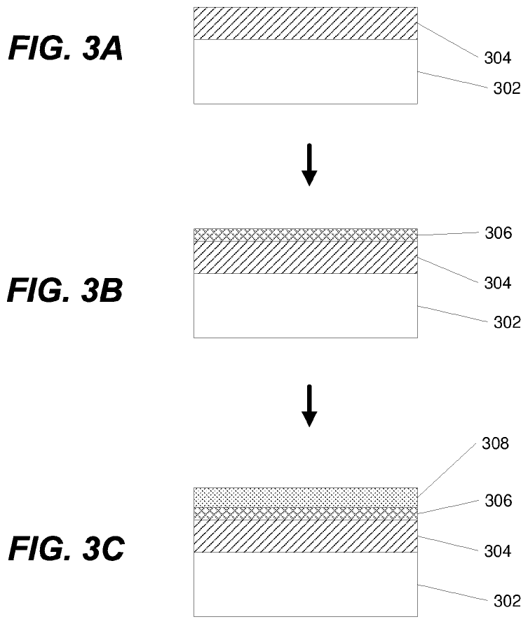

FIGS. 3A-3C depict stages in the fabrication of a non-limiting patterning structure, as described herein. The patterning structure shown in FIG. 3C has a hardmask 304 disposed on a substrate 302 (e.g., a wafer or a partially fabricated semiconductor device film stack). An imaging layer 308 is disposed over the hardmask 304. An underlayer 306 is disposed between the hardmask 304 and the imaging layer 308. Optionally, a diffusion barrier layer (not shown) may be positioned between the underlayer and the hardmask layer. The underlayer 306 can be configured to increase adhesion between the hardmask and the imaging layer, as well as to reduce radiation dose for effective photoresist exposure.

In test structures in accordance with described embodiments, DtS performance of EUV PR on an amorphous carbon AHM with an underlayer, as described herein, is as good as or even better than EUV PR on SOC, in some cases decreasing required dose by 10% or more. Furthermore, post-development peeling of the EUV PR from the hardmask bilayer (amorphous carbon AHM with a photoresist underlayer) is not observed.

The underlayer 306 can further provide increased etch selectivity and/or decreased line edge and line width roughness (LER/LWR) in the structure. In test structures in accordance with described embodiments, LER/LWR were as about good to as much as 25% or more improved relative to EUV PR on AHM or SOC.

Referring again to FIGS. 3A-3C, an implementation of the fabrication of the structure of FIG. 3C is illustrated in FIGS. 3A-3B. Such as described above with reference to FIG. 1, FIG. 3A shows the hardmask 304 disposed on the substrate 302, and FIG. 3B shows the underlayer 306 deposited on the hardmask 304.

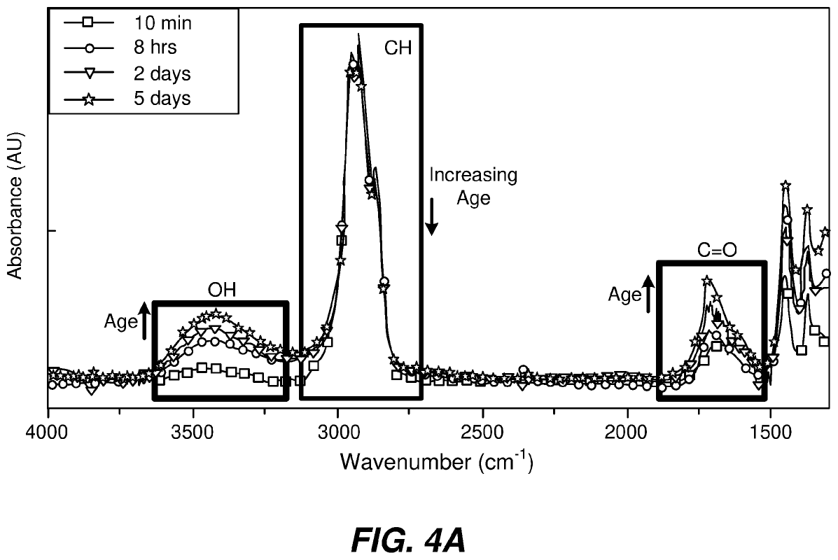

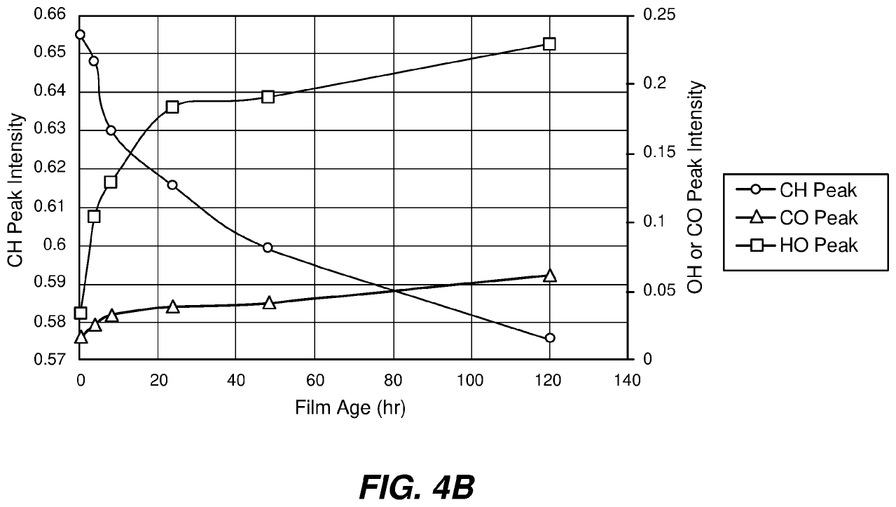

FIG. 4A is an FTIR spectrum of an amorphous carbon underlayer recorded over time to illustrate aging of an untreated underlayer. Qtime is the time between underlayer deposition and the FTIR analysis. Over time, as the film ages, C—H peak area decreases, and OH and C═O peak area increases. FIG. 4B is a graph of the integrated intensities of FTIR peaks recorded over time to illustrate aging of an untreated underlayer.

The change in the spectra over time suggests that C—H bonds are oxidized over time and therefore that the underlayer is not stable in air over a period of days. The methods described herein have been designed to overcome this phenomenon by treating the underlayer to stabilize it.

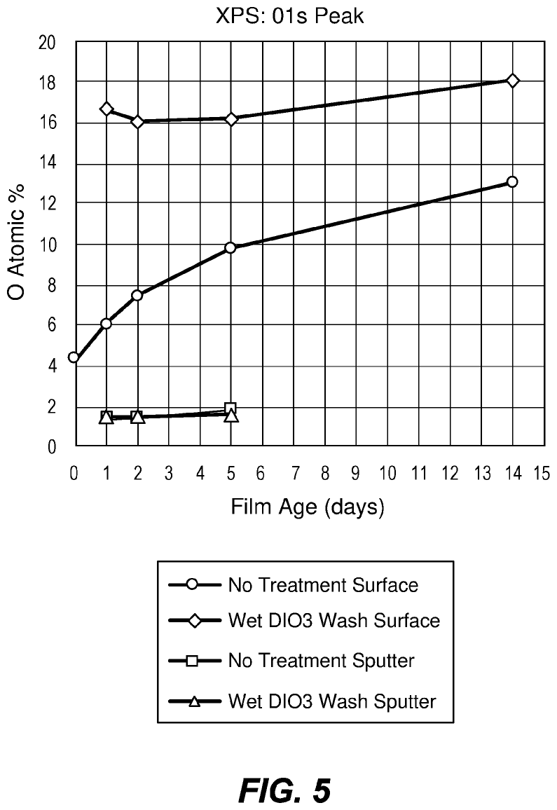

FIG. 5 is a graph of an x-ray photoelectron spectroscopic aging study of an underlayer in the presence or absence of a wet oxidative pretreatment in accordance with certain disclosed embodiments. The y-axis shows the oxygen atomic percent was calculated from the O1s peak and the x-axis shows the Qtime (time between underlayer and XPS measurement) or age of the underlayer in days. In this example, an underlayer which does not receive an oxidative treatment as described herein shows significant oxidation with age (i.e. oxygen atomic % increases). Upon a wet oxidative treatment, the top surface is stabilized against further oxidation shown by the oxygen at % remaining stable as the film ages. In this example, the wash was 30 ppm of ozone, followed by a rinse with water and then a drying with an inert gas such as nitrogen. Additionally, after Ar⁺ sputtering for a depth of 5 nm into the film both show identical amounts of oxygen. Without wishing to be bound by theory, this suggests that the oxidative treatment of the underlayer is restricted to the surface of the film. As a result, bulk properties and bulk performance characteristics (i.e. etch resistance) of the underlayer film should remain unchanged.

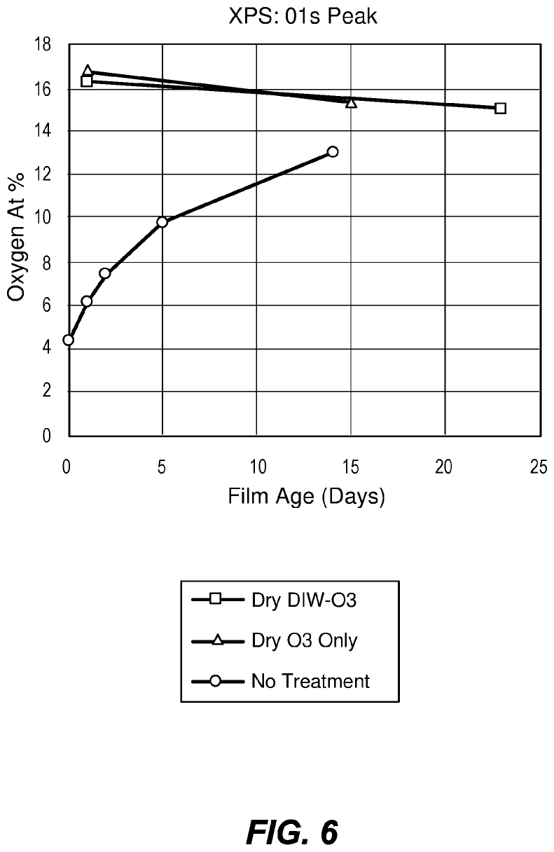

FIG. 6 is a graph of an x-ray photoelectron spectroscopic aging study of a dry oxidative pretreatment of an amorphous carbon underlayer in accordance with certain disclosed embodiments. Untreated film data points are represented by circle symbols, deionized water vapor/ozone dry treatment data points are represented by square symbols and ozone only dry treatment data points are represented by triangle symbols. The y-axis shows the oxygen atomic percentage calculated from the O1s peak and the x-axis shows the Qtime (age) of the treated and untreated underlayers in days. The data indicates that an underlayer which does not receive an oxidative treatment as described herein shows significant oxidation with age (i.e. oxygen atomic percentage increases). After dry oxidative treatment, the top surface is stabilized against further oxidation as shown by the stabilized oxygen percentages.

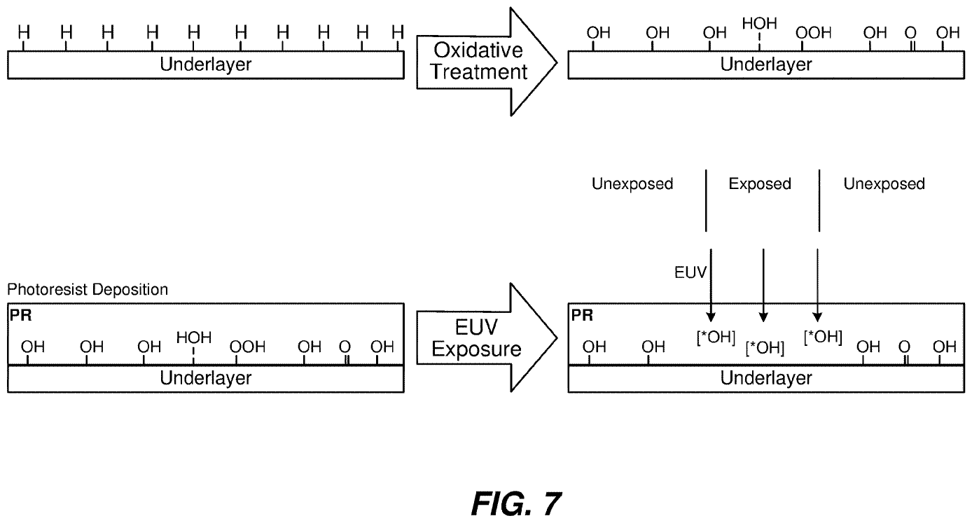

FIG. 7 is an illustration of the effect of an oxidative treatment on the top surface of an underlayer beneath an imaging layer having exposed regions and unexposed regions. Without wishing to be bound by theory, it represents a potential mechanism to reduce dose to size, enhance resist contrast and enhance the stability of the underlayer. First, the underlayer undergoes the oxidative treatment to introduce (air stable) oxygen containing moieties (i.e. OH, hydrogen bonded H2O) at the top surface of the underlayer. Then the photoresist is deposited on top of the treated underlayer and it is exposed to EUV radiation.

The potential mechanism to explain the observed DtS reduction and enhanced resist contrast is as follows. The EUV photons provide sufficient energy to ionize the surface bound oxygen containing moieties (i.e. C—OH or H₂O) to generate reactive oxygen species (i.e. radicals). These reactive oxygen species diffuse into the adjacent photoresist layer and assist in cross-linking. Since these reactive oxygen species are only generated in the EUV exposed regions they would increase the contrast between exposed and unexposed regions.

The underlayer may be an amorphous carbon underlayer. The underlayer includes a top underlayer surface and a bottom underlayer surface; and the imaging layer above it includes a top imaging layer surface and a bottom imaging layer surface. When an underlayer is oxidatively pretreated as described herein, upon EUV radiation, OH radical species or other reactive species generated from adsorbed water or hydroperoxyls may be generated which can then induce cross-linking in the exposed regions.

### Apparatus

The present disclosure also includes any apparatus configured to perform any methods described herein. In one embodiment, the apparatus for depositing a film includes a deposition module comprising a chamber for depositing one or more precursor(s) to provide an underlayer and/or an imaging layer; a patterning module comprising an EUV photolithography tool with a source of sub-30 nm wavelength radiation; and a development module comprising a chamber for developing a film including such layers.

The apparatus can further include a controller having instructions for such modules. In one embodiment, the controller includes one or more memory devices, one or more processors, and system control software coded with instructions for conducting deposition of the film. Such includes can include for, in the deposition module, depositing one or more precursor(s) to provide an underlayer and/or an imaging layer; in the patterning module, patterning the layer(s) with sub-30 nm resolution directly by EUV exposure, thereby forming a pattern within the film; and in the development module, developing the film. In particular embodiments, the development module provides for removal of the EUV exposed or EUV unexposed area(s), thereby providing a pattern within the film.

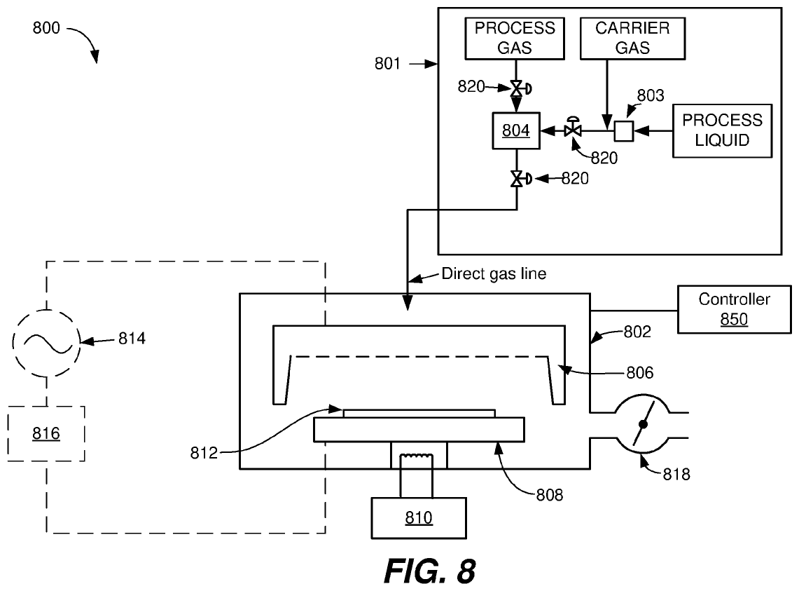

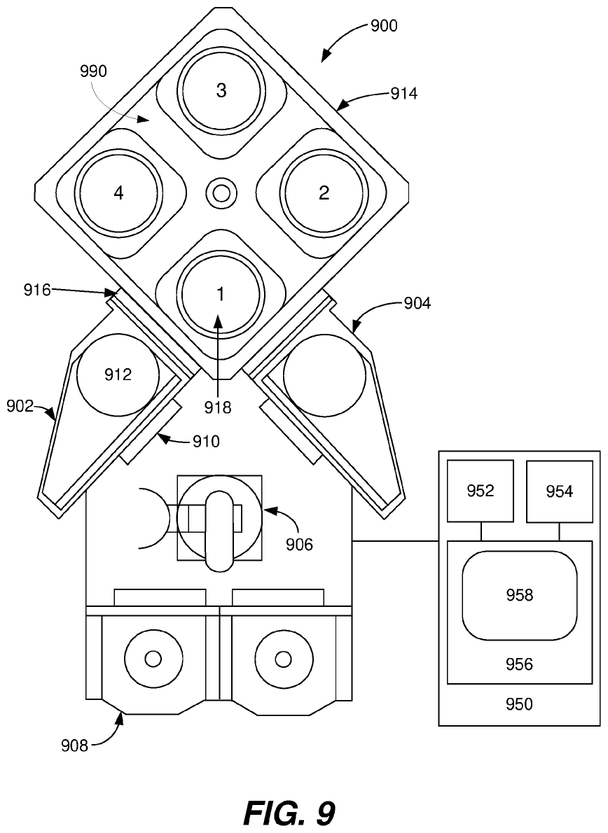

FIG. 8 depicts a schematic illustration of an embodiment of process station 800 having a process chamber body 802 for maintaining a low-pressure environment that is suitable for implementation of described vapor deposition and dry development embodiments as described herein. A plurality of process stations 800 may be included in a common low-pressure process tool environment. For example, FIG. 9 depicts an embodiment of a multi-station processing tool 900. In some embodiments, one or more hardware parameters of the process station 800 including those discussed in detail below may be adjusted programmatically by one or more computer controllers 850.

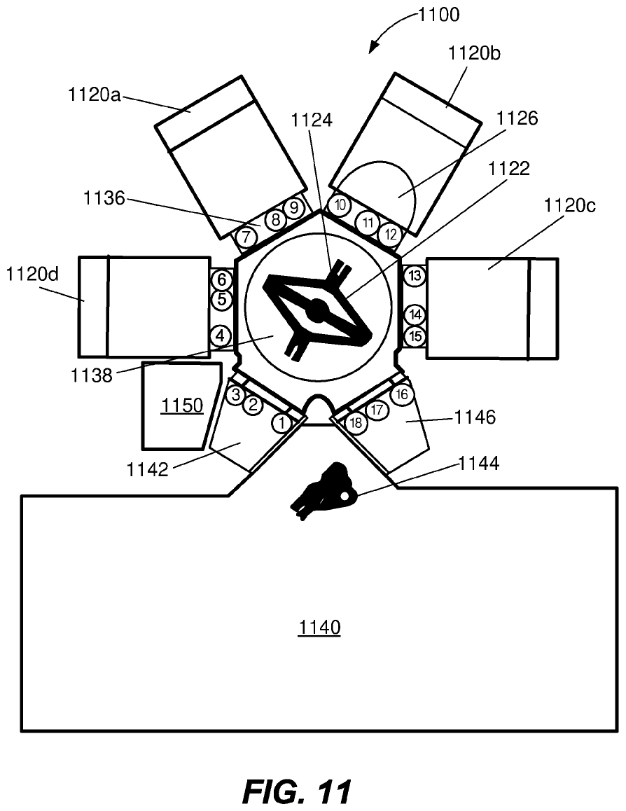

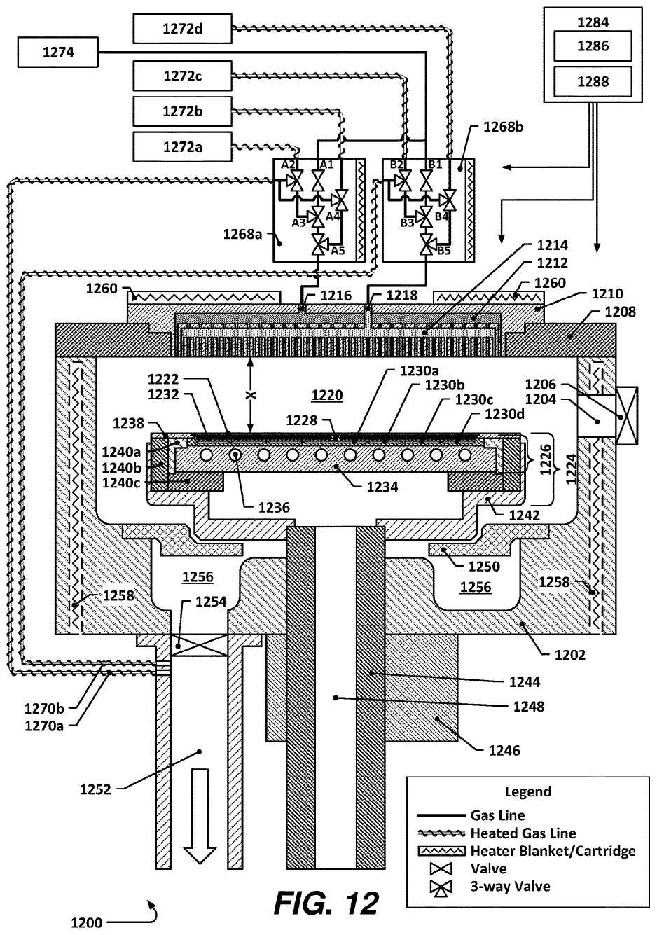

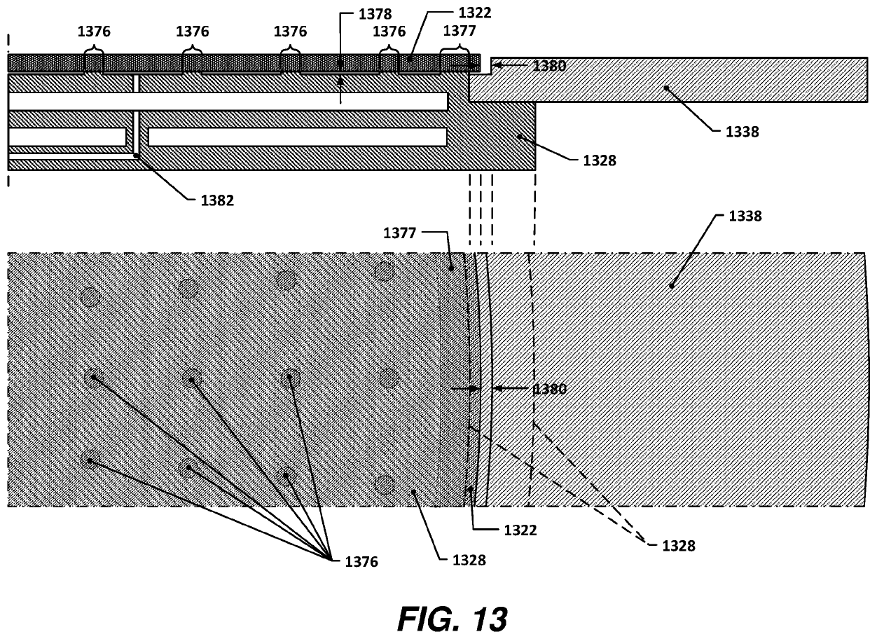

A process station may be configured as a module in a cluster tool. FIG. 11 depicts a semiconductor process cluster tool architecture with vacuum-integrated deposition and patterning modules suitable for implementation of the embodiments described herein. Such a cluster process tool architecture can include PR and underlayer deposition, resist exposure (EUV scanner), resist dry development and etch modules, as described above and further below with reference to FIGS. 12-13.

In some embodiments, certain of the processing functions can be performed consecutively in the same module, for example vapor deposition (e.g., PECVD), dry development and etch. And embodiments of this disclosure are directed to apparatus for processing a substrate, the apparatus having a process chamber comprising a substrate support, a process gas source connected with the process chamber and associated flow-control hardware, substrate handling hardware connected with the process chamber, and a controller having a processor and a memory. In some implementations, the processer and the memory are communicatively connected with one another, the processor is at least operatively connected with the flow-control and substrate handling hardware, and the memory stores computer-executable instructions for conducting the operations in the methods of making a pattering structure described herein.

For example, the memory may store computer-executable instructions for providing a hardmask disposed on a substrate, for example by chemical vapor deposition (e.g., PECVD). As described above, suitable hardmasks may be amorphous carbon ashable hardmask films, undoped or doped with B or W, for example.

The memory may further store instructions for depositing an underlayer on the substrate and/or the hardmask, where the underlayer is configured to increase adhesion between the substrate and/or the hardmask and a subsequently formed EUV-sensitive inorganic photoresist, and to reduce EUV dose for effective EUV exposure of the photoresist. For example, as described above the underlayer may be or include a vapor deposited film of hydrogenated carbon doped with a non-carbon heteroatom (e.g., any herein, such as O, Si, N, W, B, I, Cl, etc.), the film having a thickness of no more than about 25 nm, and may include about 0-30% O. In some implementations, the underlayer may be vapor deposited on the substrate and/or the hardmask by PECVD or ALD using a hydrocarbon precursor and/or a dopant precursor. In other implementations, the underlayer may be vapor deposited on the substrate and/or the hardmask by PECVD or ALD using an oxocarbon precursor that co-reacts with H₂ or a hydrocarbon. In variations on this implementation, the oxocarbon precursor may further co-react with a Si source dopant during the deposition. In other implementations, the underlayer may be vapor deposited on the substrate and/or the hardmask by PECVD or ALD using a Si-containing precursor that co-reacts with an oxidizer (e.g., any O-containing precursor described herein). In variations on this implementation, the Si-containing precursor further co-reacts with a C source dopant. In some implementations, the underlayer may be vapor deposited on the substrate and/or the hardmask by PECVD as a termination operation of a vapor deposition on the substrate or vapor deposition of the hardmask on the substrate, for example by adjusting the precursor flows entering the PECVD process chamber to achieve the desired composition of the underlayer.

The memory may further store instructions for forming an EUV-sensitive inorganic photoresist is formed on the photoresist underlayer. A suitable EUV-sensitive inorganic photoresist may be a metal oxide film, such as a EUV-sensitive tin oxide-based photoresist, such as described above.

Returning to FIG. 8, process station 800 fluidly communicates with reactant delivery system 801 for delivering process gases to a distribution showerhead 806. Reactant delivery system 801 optionally includes a mixing vessel 804 for blending and/or conditioning process gases, for delivery to showerhead 806. One or more mixing vessel inlet valves 820 may control introduction of process gases to mixing vessel 804. Where plasma exposure is used, plasma may also be delivered to the showerhead 806 or may be generated in the process station 800. As noted above, in at least some embodiments, non-plasma thermal exposure is favored.

FIG. 8 includes an optional vaporization point 803 for vaporizing liquid reactant to be supplied to the mixing vessel 804. In some embodiments, a liquid flow controller (LFC) upstream of vaporization point 803 may be provided for controlling a mass flow of liquid for vaporization and delivery to process station 800. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM.

Showerhead 806 distributes process gases toward substrate 812. In the embodiment shown in FIG. 8, the substrate 812 is located beneath showerhead 806 and is shown resting on a pedestal 808. Showerhead 806 may have any suitable shape and may have any suitable number and arrangement of ports for distributing process gases to substrate 812.

In some embodiments, pedestal 808 may be raised or lowered to expose substrate 812 to a volume between the substrate 812 and the showerhead 806. It will be appreciated that, in some embodiments, pedestal height may be adjusted programmatically by a suitable computer controller 850.

In some embodiments, pedestal 808 may be temperature controlled via heater 810. In some embodiments, the pedestal 808 may be heated to a temperature of greater than 0° C. and up to 300° C. or more, for example 50 to 120° C., such as about 65 to 80° C., during non-plasma thermal exposure of a photopatterned resist to hydrogen halide dry development chemistry, such as HBr or HCl.

Further, in some embodiments, pressure control for process station 800 may be provided by a butterfly valve 818. As shown in the embodiment of FIG. 8, butterfly valve 818 throttles a vacuum provided by a downstream vacuum pump (not shown). However, in some embodiments, pressure control of process station 800 may also be adjusted by varying a flow rate of one or more gases introduced to the process station 800.

In some embodiments, a position of showerhead 806 may be adjusted relative to pedestal 808 to vary a volume between the substrate 812 and the showerhead 806. Further, it will be appreciated that a vertical position of pedestal 808 and/or showerhead 806 may be varied by any suitable mechanism within the scope of the present disclosure. In some embodiments, pedestal 808 may include a rotational axis for rotating an orientation of substrate 812. It will be appreciated that, in some embodiments, one or more of these example adjustments may be performed programmatically by one or more suitable computer controllers 850.

Where plasma may be used, for example in gentle plasma-based dry development embodiments and/or etch operations conducted in the same chamber, showerhead 806 and pedestal 808 electrically communicate with a RF power supply 814 and matching network 816 for powering a plasma. In some embodiments, the plasma energy may be controlled by controlling one or more of a process station pressure, a gas concentration, an RF source power, an RF source frequency, and a plasma power pulse timing. For example, RF power supply 814 and matching network 816 may be operated at any suitable power to form a plasma having a desired composition of radical species. Examples of suitable powers are up to about 500 W. Likewise, RF power supply 814 may provide RF power of any suitable frequency. In some embodiments, RF power supply 814 may be configured to control high-and low-frequency RF power sources independently of one another. Examples of low-frequency RF frequencies may include, but are not limited to, frequencies between 50 kHz and 1000 kHz. Examples of high-frequency RF frequencies may include, but are not limited to, frequencies between 1.8 MHz and 2.45 GHz (e.g., about 13.56 MHz). It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas. The RF power supply may be operated at any suitable duty cycle. Examples of suitable duty cycles include, but are not limited to, duty cycles of between about 5% and 90%. Acceptable process pressures are between about 20 mTorr to 5 Torr.

In some examples, RF power can be continuous or pulsed between one or more levels. If pulsed operation is used, pulsing can be performed at a frequency in a range from 1 Hz to 1 MHz. In some examples, chamber pressure is maintained at a predetermined pressure in a range from 5 m Torr to 450 mTorr. In other examples, deposition and treatment are performed at a pressure in a range from 5 mTorr to 150 mTorr. In still other examples, deposition and treatment are performed at a pressure in a range from 5 mTorr to 35 mTorr.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, instructions for a controller 850 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a recipe phase may include instructions for setting a flow rate of a photoresist underlayer oxocarbon precursor and H₂ or hydrocarbon co-reactants and optional dopants. In some embodiments, the controller 850 may include any of the features described below with respect to system controller 950 of FIG. 9.

As described above, one or more process stations may be included in a multi station processing tool. FIG. 9 shows a schematic view of an embodiment of a multi station processing tool 900 with an inbound load lock 902 and an outbound load lock 904, either or both of which may include a remote plasma source. A robot 906 at atmospheric pressure is configured to move wafers from a cassette loaded through a pod 908 into inbound load lock 902 via an atmospheric port 910. A wafer is placed by the robot 906 on a pedestal 912 in the inbound load lock 902, the atmospheric port 910 is closed, and the load lock is pumped down. Where the inbound load lock 902 includes a remote plasma source, the wafer may be exposed to a remote plasma treatment to treat a surface in the load lock prior to being introduced into a processing chamber 914. Further, the wafer also may be heated in the inbound load lock 902 as well, for example, to remove moisture and adsorbed gases. Next, a chamber transport port 916 to processing chamber 914 is opened, and another robot (not shown) places the wafer into the reactor on a pedestal of a first station shown in the reactor for processing. While the embodiment depicted in FIG. 9 includes load locks, it will be appreciated that, in some embodiments, direct entry of a wafer into a process station may be provided.

The depicted processing chamber 914 includes four process stations, numbered from 1 to 4 in the embodiment shown in FIG. 9. Each station has a heated pedestal (shown at 918 for station 1), and gas line inlets. It will be appreciated that in some embodiments, each process station may have different or multiple purposes. For example, in some embodiments, a process station may be switchable between dry development and etch process modes. Additionally, or alternatively, in some embodiments, processing chamber 914 may include one or more matched pairs of dry development and etch process stations. While the depicted processing chamber 914 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 9 depicts an embodiment of a wafer handling system 990 for transferring wafers within the processing chamber 914. In some embodiments, wafer handling system 990 may transfer wafers between various process stations and/or between a process station and a load lock. It will be appreciated that any suitable wafer handling system may be employed. Non-limiting examples include wafer carousels and wafer handling robots. FIG. 9 also depicts an embodiment of a system controller 950 employed to control process conditions and hardware states of process tool 900. System controller 950 may include one or more memory devices 956, one or more mass storage devices 954, and one or more processors 952. Processor 952 may include a CPU or computer, analog, and/or digital input/output connections, stepper motor controller boards, etc.

In some embodiments, system controller 950 controls all of the activities of process tool 900. System controller 950 executes system control software 958 stored in mass storage device 954, loaded into memory device 956, and executed on processor 952. Alternatively, the control logic may be hard coded in the controller 950. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 958 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 900. System control software 958 may be configured in any suitable way. For example, various process tool component subroutines or control objects may be written to control operation of the process tool components used to carry out various process tool processes. System control software 958 may be coded in any suitable computer readable programming language.

In some embodiments, system control software 958 may include input/output control (IOC) sequencing instructions for controlling the various parameters described above. Other computer software and/or programs stored on mass storage device 954 and/or memory device 956 associated with system controller 950 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 918 and to control the spacing between the substrate and other parts of process tool 900.

A process gas control program may include code for controlling hydrogen halide gas composition (e.g., HBr or HCl gas as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 450. The user interface may include a display screen, graphical software displays of the apparatus and/or process conditions, and user input devices such as pointing devices, keyboards, touch screens, microphones, etc.

In some embodiments, parameters adjusted by the system controller 950 may relate to process conditions. Non-limiting examples include process gas composition and flow rates, temperature, pressure, plasma conditions (such as RF bias power levels, frequency, and exposure time), etc. These parameters may be provided to the user in the form of a recipe, which may be entered utilizing the user interface.

Signals for monitoring the process may be provided by analog and/or digital input connections of system controller 950 from various process tool sensors. The signals for controlling the process may be output on the analog and digital output connections of process tool 900. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 950 may provide program instructions for implementing the above-described deposition processes. The program instructions may control a variety of process parameters, such as direct current (DC) power level, RF bias power level, pressure, temperature, etc. The instructions may control the parameters to operate photoresist underlayer deposition processes according to various embodiments described herein.

The system controller 950 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 950.

In some implementations, the system controller 950 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 950, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 950 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 950 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 950, in some implementations, may be a part of or coupled to a computer that is integrated with, coupled to the system, otherwise networked to the system, or a combination thereof. For example, the system controller 950 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 950 receives instructions in the form of data, which specify parameters for each of the processing steps to be performed during one or more operations. It should be understood that the parameters may be specific to the type of process to be performed and the type of tool that the system controller 950 is configured to interface with or control. Thus, as described above, the system controller 950 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the system controller 950 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Inductively coupled plasma (ICP) reactors which, in certain embodiments, may be suitable for etch operations suitable for implementation of some embodiments, are now described. Although ICP reactors are described herein, in some embodiments, it should be understood that capacitively coupled plasma reactors may also be used.

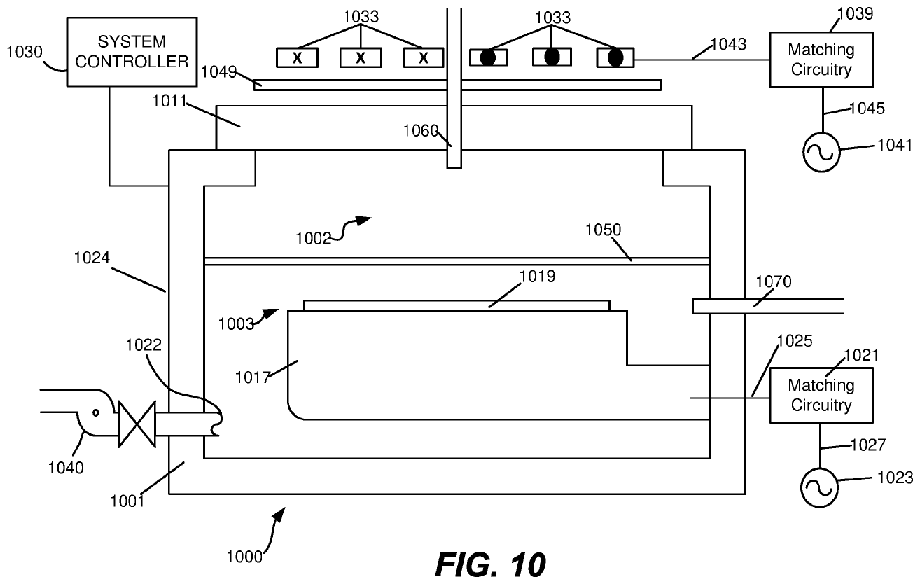

FIG. 10 schematically shows a cross-sectional view of an inductively coupled plasma apparatus 1000 appropriate for implementing certain embodiments or aspects of embodiments such as vapor (dry) deposition, dry development and/or etch. In other embodiments, other tools or tool types having the functionality to conduct the dry deposition, development and/or etch processes described herein may be used for implementation.

The inductively coupled plasma apparatus 1000 includes an overall process chamber 1024 structurally defined by chamber walls 1001 and a window 1011. The chamber walls 1001 may be fabricated from stainless steel or aluminum. The window 1011 may be fabricated from quartz or other dielectric material. An optional internal plasma grid 1050 divides the overall process chamber into an upper sub-chamber 1002 and a lower sub chamber 1003. In most embodiments, plasma grid 1050 may be removed, thereby utilizing a chamber space made of sub chambers 1002 and 1003. A chuck 1017 is positioned within the lower sub-chamber 1003 near the bottom inner surface. The chuck 1017 is configured to receive and hold a semiconductor wafer 1019 upon which the etching and deposition processes are performed. The chuck 1017 can be an electrostatic chuck for supporting the wafer 1019 when present. In some embodiments, an edge ring (not shown) surrounds chuck 1017 and has an upper surface that is approximately planar with a top surface of the wafer 1019, when present over chuck 1017. The chuck 1017 also includes electrostatic electrodes for chucking and dechucking the wafer 1019. A filter and DC clamp power supply (not shown) may be provided for this purpose. Other control systems for lifting the wafer 1019 off the chuck 1017 can also be provided. The chuck 1017 can be electrically charged using an RF power supply 1023. The RF power supply 1023 is connected to matching circuitry 1021 through a connection 1027. The matching circuitry 1021 is connected to the chuck 1017 through a connection 1025. In this manner, the RF power supply 1023 is connected to the chuck 1017. In various embodiments, a bias power of the electrostatic chuck may be set at about 50V or may be set at a different bias power depending on the process performed in accordance with disclosed embodiments. For example, the bias power may be between about 20 V and about 100 V, or between about 30 V and about 150 V.

Elements for plasma generation include a coil 1033 is positioned above window 1011. In some embodiments, a coil is not used in disclosed embodiments. The coil 1033 is fabricated from an electrically conductive material and includes at least one complete turn. The example of a coil 1033 shown in FIG. 10 includes three turns. The cross sections of coil 1033 are shown with symbols, and coils having an “X” extend rotationally into the page, while coils having a “●” extend rotationally out of the page. Elements for plasma generation also include an RF power supply 1041 configured to supply RF power to the coil 1033. In general, the RF power supply 1041 is connected to matching circuitry 1039 through a connection 1045. The matching circuitry 1039 is connected to the coil 1033 through a connection 1043. In this manner, the RF power supply 1041 is connected to the coil 1033. An optional Faraday shield 1049 is positioned between the coil 1033 and the window 1011. The Faraday shield 1049 may be maintained in a spaced apart relationship relative to the coil 1033. In some embodiments, the Faraday shield 1049 is disposed immediately above the window 1011. In some embodiments, the Faraday shield 1049 is between the window 1011 and the chuck 1017. In some embodiments, the Faraday shield 1049 is not maintained in a spaced apart relationship relative to the coil 1033. For example, the Faraday shield 1049 may be directly below the window 1011 without a gap. The coil 1033, the Faraday shield 1049, and the window 1011 are each configured to be substantially parallel to one another. The Faraday shield 1049 may prevent metal or other species from depositing on the window 1011 of the process chamber 1024.

Process gases may be flowed into the process chamber through one or more main gas flow inlets 1060 positioned in the upper sub-chamber 1002 and/or through one or more side gas flow inlets 1070. Likewise, though not explicitly shown, similar gas flow inlets may be used to supply process gases to a capacitively coupled plasma processing chamber. A vacuum pump, e.g., a one or two stage mechanical dry pump and/or turbomolecular pump 1040, may be used to draw process gases out of the process chamber 1024 and to maintain a pressure within the process chamber 1024. For example, the vacuum pump may be used to evacuate the lower sub-chamber 1003 during a purge operation of ALD. A valve-controlled conduit may be used to fluidically connect the vacuum pump to the process chamber 1024 so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 1000, one or more process gases may be supplied through the gas flow inlets 1060 and/or 1070. In certain embodiments, process gas may be supplied only through the main gas flow inlet 1060, or only through the side gas flow inlet 1070. In some cases, the gas flow inlets shown in the figure may be replaced by more complex gas flow inlets, one or more showerheads, for example. The Faraday shield 1049 and/or optional grid 1050 may include internal channels and holes that allow delivery of process gases to the process chamber 1024. Either or both of Faraday shield 1049 and optional grid 1050 may serve as a showerhead for delivery of process gases. In some embodiments, a liquid vaporization and delivery system may be situated upstream of the process chamber 1024, such that once a liquid reactant or precursor is vaporized, the vaporized reactant or precursor is introduced into the process chamber 1024 via a gas flow inlet 1060 and/or 1070.

Radio frequency power is supplied from the RF power supply 1041 to the coil 1033 to cause an RF current to flow through the coil 1033. The RF current flowing through the coil 1033 generates an electromagnetic field about the coil 1033. The electromagnetic field generates an inductive current within the upper sub-chamber 1002. The physical and chemical interactions of various generated ions and radicals with the wafer 1019 etch features of and selectively deposit layers on the wafer 1019.

If the plasma grid 1050 is used such that there is both an upper sub-chamber 1002 and a lower sub-chamber 1003, the inductive current acts on the gas present in the upper sub-chamber 1002 to generate an electron-ion plasma in the upper sub-chamber 1002. The optional internal plasma grid 1050 limits the amount of hot electrons in the lower sub-chamber 1003. In some embodiments, the apparatus 1000 is designed and operated such that the plasma present in the lower sub-chamber 1003 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 1003 through port 1022. The chuck 1017 disclosed herein may operate at elevated temperatures ranging between about 10° C. and about 250° C.. The temperature will depend on the process operation and specific recipe.

Apparatus 1000 may be coupled to facilities (not shown) when installed in a clean room or a fabrication facility. Facilities include plumbing that provide processing gases, vacuum, temperature control, and environmental particle control. These facilities are coupled to apparatus 1000, when installed in the target fabrication facility. Additionally, apparatus 1000 may be coupled to a transfer chamber that allows robotics to transfer semiconductor wafers into and out of apparatus 1000 using typical automation.

In some embodiments, a system controller 1030 (which may include one or more physical or logical controllers) controls some or all of the operations of a process chamber 1024. The system controller 1030 may include one or more memory devices and one or more processors. In some embodiments, the apparatus 1000 includes a switching system for controlling flow rates and durations when disclosed embodiments are performed. In some embodiments, the apparatus 1000 may have a switching time of up to about 500 ms, or up to about 750 ms. Switching time may depend on the flow chemistry, recipe chosen, reactor architecture, and other factors.

In some implementations, the system controller 1030 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 1030, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 1030 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 1030, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 1030 receives instructions in the form of data, which specify parameters for each of the processing steps to be performed during one or more operations. It should be understood that the parameters may be specific to the type of process to be performed and the type of tool that the controller is configured to interface with or control. Thus, as described above, the system controller 1030 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (e.g., PECVD) chamber or module, an ALD chamber or module, an ALE chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner. The EUVL patterning tool may be a standalone device from which the substrate is moved into and out of for deposition and etching as described herein. Or, as described below, the EUVL patterning tool may be a module on a larger multi-component tool.

FIG. 11 depicts a semiconductor process cluster tool architecture 1100 with vacuum-integrated deposition, EUV patterning and dry development/etch modules that interface with a vacuum transfer module, suitable for implementation of the processes described herein. While the processes may be conducted without such vacuum integrated apparatus, such apparatus may be advantageous in some implementations.

FIG. 11 depicts a semiconductor process cluster tool architecture with vacuum-integrated deposition and patterning modules that interface with a vacuum transfer module, suitable for implementation of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster.

A vacuum transport module (VTM) 1138 interfaces with four processing modules 1120a-1120d, which may be individually optimized to perform various fabrication processes. By way of example, processing modules 1120a-1120d may be implemented to perform deposition, evaporation, dry development, etch, strip, and/or other semiconductor processes. For example, module 1120a may be an ALD reactor that may be operated to perform in a non-plasma, thermal atomic layer depositions as described herein. And module 1120b may be a PECVD tool. It should be understood that the figure is not necessarily drawn to scale.

Airlocks 1142 and 1146, also known as a loadlocks or transfer modules, interface with the VTM 1138 and a patterning module 1140. For example, as noted above, a suitable patterning module may be the TWINSCAN NXE: 3300B® platform supplied by ASML of Veldhoven, NL). This tool architecture allows for work pieces, such as semiconductor substrates or wafers, to be transferred under vacuum so as not to react before exposure. Integration of the deposition modules with the lithography tool is facilitated by the fact that EUVL also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a more conventional stand-alone EUVL scanner and a deposition reactor, either stand alone or integrated in a cluster architecture with other tools, such as etch, strip etc., as modules, for example as described with reference to FIG. 10 but without the integrated patterning module.

Airlock 1142 may be an “outgoing” loadlock, referring to the transfer of a substrate out from the VTM 1138 serving a deposition module 1120a to the patterning module 1140, and airlock 1146 may be an “ingoing” loadlock, referring to the transfer of a substrate from the patterning module 1140 back in to the VTM 1138. The ingoing loadlock 1146 may also provide an interface to the exterior of the tool for access and egress of substrates. Each process module has a facet that interfaces the module to VTM 1138. For example, deposition process module 1120a has facet 1136. Inside each facet, sensors, for example, sensors 1-18 as shown, are used to detect the passing of wafer 1126 when moved between respective stations. Patterning module 1140 and airlocks 1142 and 1146 may be similarly equipped with additional facets and sensors, not shown.

Main VTM robot 1122 transfers wafer 1126 between modules, including airlocks 1142 and 1146. In one embodiment, robot 1122 has one arm, and in another embodiment, robot 1122 has two arms, where each arm has an end effector 1124 to pick wafers such as wafer 1126 for transport. Front-end robot 1144, in is used to transfer wafers 1126 from outgoing airlock 1142 into the patterning module 1140, from the patterning module 1140 into ingoing airlock 1146. Front-end robot 1144 may also transport wafers 1126 between the ingoing loadlock and the exterior of the tool for access and egress of substrates. Because ingoing airlock module 1146 has the ability to match the environment between atmospheric and vacuum, the wafer 1126 is able to move between the two pressure environments without being damaged.

It should be noted that a EUVL tool typically operates at a higher vacuum than a deposition tool. If this is the case, it is desirable to increase the vacuum environment of the substrate during the transfer between the deposition to the EUVL tool to allow the substrate to degas prior to entry into the patterning tool. Outgoing airlock 1142 may provide this function by holding the transferred wafers at a lower pressure, no higher than the pressure in the patterning module 1140, for a period of time and exhausting any off-gassing, so that the optics of the patterning tool 1140 are not contaminated by off-gassing from the substrate. A suitable pressure for the outgoing, off-gassing airlock is no more than 1E-8 Torr.

In some embodiments, a system controller 1150 (which may include one or more physical or logical controllers) controls some or all of the operations of the cluster tool and/or its separate modules. It should be noted that the controller can be local to the cluster architecture, or can be located external to the cluster architecture in the manufacturing floor, or in a remote location and connected to the cluster architecture via a network. The system controller 1150 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

In various embodiments, an apparatus for forming a negative pattern mask is provided. The apparatus may include a processing chamber for patterning, deposition and etch, and a controller including instructions for forming a negative pattern mask. The instructions may include code for, in the processing chamber, patterning a feature in a chemically amplified (CAR) resist on a semiconductor substrate by EUV exposure to expose a surface of the substrate, dry developing the photopatterned resist, and etching the underlying layer or layer stack using the patterned resist as a mask.

It should be noted that the computer controlling the wafer movement can be local to the cluster architecture or can be located external to the cluster architecture in the manufacturing floor, or in a remote location and connected to the cluster architecture via a network. A controller as described above with respect to any of FIGS. 8, 9, or 10 may be implemented with the tool in FIG. 11.

FIG. 12 shows an example of a deposition chamber (e.g., for vapor-based deposition, such as for an imaging layer and/or an under layer). As can be seen, the apparatus 1200 includes a processing chamber 1202 having a lid 1208 and a wafer transfer passage 1204, which is sized to allow a substrate 1222 to be passed therethrough and to be placed on a wafer support 1224. The wafer transfer passage 1204 may have a gate valve 1206 or similar door mechanism that may be operated to seal or unseal the wafer transfer passage. For example, the processing chamber 1202 may be provided substrates 1222 via a wafer handling robot that is located in an adjoining transfer chamber.

The wafer support 1224 may include an electrostatic chuck (ESC) 1226 to provide a wafer support surface for the substrate 1222. The ESC 1226 may include a base plate 1234 that is bonded to a top surface of the top plate 1228. In the depicted example, the top plate 1228 has two separate electrical systems embedded within it. One such system is an electrostatic clamping electrode system having one or more clamping electrodes 1232 to generate an electric charge within the substrate 1222 that causes the substrate 1222 to be drawn against the wafer support surface of the top plate 1228.

The other system is a thermal control system to control the temperature of the substrate 1222 during processing conditions. In FIG. 12, the thermal control system features four annular resistance heater traces 1230a, 1230b, 1230c, and 1230d positioned beneath the clamping electrodes 1232. Each resistance heater trace 1230a/b/c/d may be individually controlled to provide a variety of radial heating profiles in the top plate 1228, for example, to maintain the substrate 1222 so as to have a temperature uniformity of ±0.5° C. in some cases. Other implementations may use single-zone or multi-zone heating systems having more or fewer than four zones. In some implementations, of, for example, temperature control mechanisms discussed above, heat pumps or Peltier junctions may be used instead of resistance heating traces.

The ESC 1226 may also include a base plate 1234 to provide structural support to the underside of the top plate 1228 and which may also act as a heat dispersion system. For example, the base plate 1234 may include one or more heat exchange passages 1236; and a heat exchange medium, e.g., water or inert fluorinated liquid, may be circulated through the heat exchange passages 1236 during use.

The ESC 1226 may be supported by a wafer support housing 1242 that is connected with, and supported by, a wafer support column 1244. The wafer support column 1244 may have a routing passage 1248 other pass-throughs for routing cabling (e.g., for providing electrical power), fluid flow conduits (e.g., for conveying heat exchange medium), and other equipment to the underside of the base plate 1234 and/or the top plate 1228.

The apparatus 1200 of FIG. 12 also includes a wafer support z-actuator 1246 that may provide movable support to the wafer support column 1244. The wafer support z-actuator 1246 may be actuated to cause the wafer support column 1244, and the wafer support 1224 supported thereby, to move up or down vertically, e.g., by up to several inches, within a reaction space 1220 of the processing chamber 1202. In doing so, a gap distance X between the substrate 1222 and the underside of the showerhead 1210 may be tuned depending on various process conditions.

The wafer support 1224 may also include one or more edge rings that may be used to control and/or fine-tune various process conditions. In FIG. 12, an upper edge ring 1238 is provided that lies on top of, for example, lower edge rings 1240a and 1240b, which, in turn, are supported by the wafer support housing 1242 and a third lower edge ring 1240c.

The apparatus 1200 may also include a system for removing process gases from the processing chamber 1202 during and after processing concludes. For example, the processing chamber 1202 may include an annular plenum 1256 that encircles the wafer support column 1244. The annular plenum 1256 may, in turn, be fluidically connected with a vacuum foreline 1252 that may be connected with a vacuum pump. A regulator valve 1254 may be provided in between the vacuum foreline 1252 and the processing chamber 1202 and actuated to control the flow into the vacuum foreline 1252. In some implementations, a baffle 1250, e.g., an annular plate or other structure that may serve to make the flow into the annular plenum 1256 more evenly distributed about the circumference of the wafer support column 1244, may be provided to reduce the chances of flow non-uniformities developing in reactants flowed across the substrate 1222.

The showerhead 1210, as shown, is a dual-plenum showerhead 1210 and includes a first plenum 1212 that is provided process gas via a first inlet 1216 and a second plenum 1214 that is provided process gas via a second inlet 1218. Two or more plenums can be employed to maintain separation between the precursor(s) and the counter-reactant(s) prior to release of the precursor and the counter-reactant. In some instances, a single plenum is used to deliver the precursor(s) into the reaction space 1220 of the processing chamber 1202. Each plenum may have a corresponding set of gas distribution ports that fluidically connect the respective plenum with the reaction space 1220 through the faceplate of the showerhead 1210 (the faceplate being the portion of the showerhead 1210 that is interposed between the lowermost plenum and the reaction space 1220).

The first inlet 1216 and the second inlet 1218 of the showerhead 1210 may be provided processing gases via a gas supply system, which may be configured to provide one or more precursor(s) and/or counter-reactant(s), as discussed herein. A first valve manifold 1268a may be configured to provide one or more precursor(s) to the first inlet 1216, while a second valve manifold 1268b may be configured to provide other precursor(s) or other reactant to the second inlet 1218. In this example, the first valve manifold 1268a, for example, includes multiple valves A1-A5. Valve A2 may, for example, be a three-way valve that has one port fluidically connected with a first vaporizer 1272 a, another port fluidically connected with a bypass line 1270a, and a third port fluidically connected with a port on another 3-way valve A3. Similarly, valve A4 may be another three-way valve that has one port fluidically connected with a second vaporizer 1272b, another port fluidically connected with the bypass line 1270a, and a third port fluidically connected with a port on another 3-way valve A5. One of the other ports on valve A5 may be fluidically connected with the first inlet 1216 while the remaining port on valve A5 may be fluidically connected with one of the remaining ports on the valve A3. The remaining port on the valve A3 may, in turn, be fluidically connected with the valve A1 which may be fluidically interposed between the valve A3 and a purge gas source 1274, e.g., nitrogen, argon, or other suitably inert gas (with respect to precursor(s) and/or counter-reactant(s)). In some embodiments, only the first valve manifold is employed.

For the purposes of this disclosure, the term “fluidically connected” is used with respect to volumes, plenums, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

The first valve manifold 1268a may, for example, be controllable to cause vapors from one or both of the vaporizers 1272a and 1272b to be flowed either to the processing chamber 1202 or through the first bypass line 1270a and into the vacuum foreline 1252, such as by controlled actuation of valves A1-A5. The first valve manifold 1268a may also be controllable to cause a purge gas to be flowed from the purge gas source 1274 and into the first inlet 1216.

It will be appreciated that the second valve manifold 1268b may be controlled in a similar manner, e.g., by controlling valves B1-B5, to provide vapors from vaporizers 1272c and 1272d to the second inlet 1218 or to the second bypass line 1270b. It will be further appreciated that different manifold arrangements may be utilized as well, including a single unitary manifold that includes valves for controlling flow of the precursor(s), counter-reactant(s), or other reactants to the first inlet 1216 and the second inlet 1218.

As mentioned earlier, some apparatuses 1200 may feature a lesser number of vapor sources, e.g., only two vaporizers 1272, in which case the valve manifold(s) 1268 may be modified to have a lesser number of valves, e.g., only valves A1-A3.

As discussed above, apparatuses such as apparatus 1200, which may be used to provide for dry deposition of films, may be configured to maintain particular temperature profiles within the processing chamber 1202. In particular, such apparatuses 1200 may be configured to maintain the substrate 1222 at a lower temperature, e.g., at least 25° C. to 50° C. lower, than most of the equipment of the apparatus 1202 that comes into direct contact with the precursor(s) and/or counter-reactant(s).

To provide for temperature control, various heating systems may be included in the apparatus 1200. For example, the processing chamber 1202 may have receptacles for receiving cartridge heaters 1258, e.g., vertical holes for receiving cartridge heaters 1258 may be bored into the four corners of the chamber 1202 housing. In some implementations, the showerhead 1210 may be covered with heater blankets 1260, which may be used to apply heat across the exposed upper surface of the showerhead 1210 to keep the showerhead temperature elevated. It may also be beneficial to heat various gas lines that are used to conduct the vaporized reactants from the vaporizers 1272 to the showerhead 1210. For example, resistive heater tape may be wound around such gas lines and used to heat them to an elevated temperature. Any of the gas lines and even the gate valve 1206 in FIG. 12 can be actively or indirectly heated.

The various operational systems of the apparatus 1200 may be controlled by a controller 1284, which may include one or more processors 1286 and one or more memory devices 1288 that are operatively connected with each other and that are communicatively connected with various systems and subsystems of the apparatus 1200 so as to provide for control functionality for those systems. For example, the controller 1284 may be configured to control the valves A1-A5 and B1-B5, the various heaters 1258, 1260, the vaporizers 1272, the regulator valve 1254, the gate valve 1206, the wafer support z-actuator, and so forth.

Another feature that the apparatus 1200 may include is shown in FIG. 13, which depicts close-up side cross-sectional and plan views of a portion of the substrate 1222, top plate 1228, and upper edge ring 1238 of FIG. 12. As can be seen, in some implementations, the substrate 1322 may be elevated off of most of the top plate 1328 by a plurality of small mesas 1376, which may be shallow bosses that protrude from the nominal upper surface of the top plate 1328 by a small distance so as to provide for a backside gap 1378 between the underside of the substrate 1322 and the majority of the top plate 1328. A circumferential wall feature 1377 may be provided at the periphery of the top plate 1328. The circumferential wall feature 1377 may extend around the entire perimeter of the top plate 1328 and be of nominally the same height as the mesas 1376. During processing operations, a generally inert gas, such as helium, may be flowed into the backside gap 1378 via one or more gas ports 1382. This gas may then flow radially outward before encountering the circumferential wall feature 1377, which way then restrict such radially outward flow and cause a higher-pressure region of the gas to be trapped between the substrate 1322 and the top plate 1328. The inert gas that leaks past the circumferential wall 1377 may eventually flow out through a radial gap 1380 between the outer edge of the substrate 1322 and a portion of the upper edge ring 1338. Such gas may serve to protect the underside of the substrate from undesirably being affected by the processing operations being performed by acting to prevent the gases released by the showerhead 1210 from reaching the underside of the substrate 1322. At the same time, the gas released into the backside gap 1378 region may also act to increase thermal coupling between the substrate 1322 and the top plate 1328, thereby allowing the top plate 1328 to more effectively heat or cool the substrate 1322. Due to the higher pressure provided by the circumferential wall, the gas that is within the backside gap 1378 region may also be at a higher density than gas in the remainder of the chamber, and may thus provide more effective thermal coupling between the substrate 1322 and the top plate 1328.

The controller 1284 may be configured, e.g., via execution of computer-executable instructions, to cause the apparatus 1200 to perform various operations consistent with the disclosure provided above.

Once the imaging layer and/or underlayer has been deposited on the substrate 1322, the substrate 1322 may, as noted above, be transferred to one or more subsequent processing chambers or tool for additional operations (e.g., any described herein). Further deposition apparatuses are described in International Patent Application No. PCT/US2020/038968, filed Jun. 22, 2020, titled “APPARATUS FOR PHOTORESIST DRY DEPOSITION,” which is herein incorporated by reference in its entirety.

FIG. 14 presents a schematic illustration of an embodiment of an underlayer oxidative treatment module 1400 for integration with a process chamber, such as the one illustrated by FIG. 8 for example. Module 1400 is configured for dry treatment. In some embodiments, the underlayer oxidative treatment module may be located inside the process chamber, while in other embodiments, the oxidative treatment module is configured to be outside the chamber, but operatively connected to the process chamber, such as through the process chamber's showerhead. Ampoule 1402 is a reservoir or tank for a liquid such as deionized water. Liquid flow controller 1404 is connected to ampoule 1402 and to vaporizer unit 1406. Liquid flow controller 1404 precisely controls the amount of liquid going to vaporizer unit 1406. In addition to the depicted schematic of FIG. 14, the ampoule 1402 may be in a bubbler configuration (not shown) or a flow over vapor configuration (not shown). If the ampoule 1402 is in a bubbler configuration or a flow over vapor configuration, a vaporizer is not necessary. Vaporizer 1406 is configured to volatilize a liquid into a gas.

Carrier gas source 1408 is connected to flow path 1410. Flow path 1410 connects vaporizer unit 1406 to showerhead 1424. Showerhead 1424 distributes reagents to the process chamber (not shown).

Oxygen gas source 1412 is a feed, connected to a flow controller 1414 to regulate the amount of oxygen fed to ozone generator unit 1416. Ozone generator unit 1416 converts oxygen sources to ozone gas. Ozone generator unit 1416 is outfitted with ozone detector 1418. Ozone detector 1418 may be within ozone generator unit 1416, or alternatively may be external to ozone generator unit 1416. The product oxygen and ozone 1420 formed by the ozone generator are conveyed via flow path 1422 to showerhead 1424. Flow controllers 1404 and 1414 can be connected to the main controller for the process chamber in certain embodiments.

In certain embodiments, the underlayer oxidative treatment module may include an ampoule assembly connected to a vaporizer and an ozone generator as illustrated by FIG. 14; or may include a plasma generator; a heater or a combination thereof.

In certain embodiments, process conditions for apparatus 1400 may include a chuck (not shown) temperature range of from about 0° C. to about 150° C.; a pressure range of from about 100 mTorr to about 10 Torr; a direct liquid injection of deionized water at a flow rate of 0 -3.0 g/min, an O₂ flow of from about 100 to about 2500 sccm in the presence of an inert carrier gas flowed at a rate of from about 0 to about 1500 sccm.

FIG. 15 depicts a cross-sectional side view of an example apparatus for the methods described herein, in accordance with disclosed embodiments. As detailed below, this apparatus 1500 is capable of rapidly and precisely controlling the temperature of a substrate, including performing thermal etching operations. The apparatus 1500 includes a processing chamber 1502, a pedestal 1504 having a substrate heater 1522 and a plurality of substrates supports 1508 configured to support a substrate 1518, and a gas distribution unit 1510.

The processing chamber 1502 includes sides walls 1512A, a top 1512B, and a bottom 1512C, that at least partially define the chamber interior 1514, which may be considered a plenum volume. As stated herein, it may be desirable in some embodiments to actively control the temperature of the processing chamber walls 1512A, top 1512B, and bottom 1512C in order to prevent unwanted condensation on their surfaces. Some emerging semiconductor processing operations flow vapors, such as water and/or alcohol vapor, onto the substrate which adsorb onto the substrate, but they may also undesirably adsorb onto the chamber's interior surfaces. This can lead to unwanted deposition and etching on the chamber interior surfaces which can damage the chamber surfaces and cause particulates to flake off onto the substrate thereby causing substrate defects. In order to reduce and prevent unwanted condensation on the chamber's interior surfaces, the temperature of chamber's walls, top, and bottom may be maintained at a temperature at which condensation of chemistries used in the processing operations does not occur.

This active temperature control of the chamber's surfaces may be achieved by using heaters to heat the chamber walls 1512A, the top 1512B, and the bottom 1512C. As illustrated in FIG. 15, chamber heaters 1516A are positioned on and configured to heat the chamber walls 1512A, chamber heaters 1516B are positioned on and configured to heat the top 1512B, and chamber heaters 1516C are positioned on and configured to heat the bottom 1512C. The chamber heaters 1516A-1516C may be resistive heaters that are configured to generate heat when an electrical current is flowed through a resistive element. Chamber heaters 1516A-1516C may also be fluid conduits through which a heat transfer fluid may be flowed, such as a heating fluid which may include heated water. In some instances, the chamber heaters 1516A-1516C may be a combination of both heating fluid and resistive heaters. The chamber heaters 1516A-1516C are configured to generate heat in order to cause the interior surfaces of each of the chamber walls 1512A, the top 1512B, and the bottom 1512C to the desired temperature, which may range between about 40° C. and about 150° C., including between about 80° C. and about 130° C., about 90 ° C. or about 120 ° C., for instance. It has been discovered that under some conditions, water and alcohol vapors do not condense on surfaces kept at about 90° C. or higher.

The chamber walls 1512A, top 1512B, and bottom 1512C, may also be comprised of various materials that can withstand the chemistries used in the processing techniques. These chamber materials may include, for example, an aluminum, anodized aluminum, aluminum with a polymer, such as a plastic, a metal or metal alloy with a yttria coating, a metal or metal alloy with a zirconia coating, and a metal or metal alloy with aluminum oxide coating; in some instances the materials of the coatings may be blended or layers of differing material combinations, such as alternating layers of aluminum oxide and yttria, or aluminum oxide and zirconia. These materials are configured to withstand the chemistries used in the processing techniques, such as anhydrous HF, water vapor, methanol, isopropyl alcohol, chlorine, fluorine gases, nitrogen gas, hydrogen gas, helium gas, and the mixtures thereof.

The apparatus 1500 may also be configured to perform processing operations at or near a vacuum, such as at a pressure of about 0.1 Torr to about 100 Torr, or about 20 Torr to about 200 Torr, or about 0.1 Torr to about 10 Torr. This may include a vacuum pump 1584 configured to pump the chamber interior 1514 to low pressures, such as a vacuum having a pressure of about 0.1 Torr to about 100 Torr, including about 0.1 Torr to about 10 Torr, and about 20 Torr to about 200 Torr, or about 0.1 Torr to about 10 Torr.

Various features of the pedestal 1504 will now be discussed. The pedestal 1504 includes a heater 1522 (encompassed by the dashed rectangle in FIG. 15) that has a plurality of LEDs 1524 that are configured to emit visible light having wavelengths including and between 400 nm to 800 nm, including 450 nm. The heater LEDs emit this visible light onto the backside of the substrate which heats the substrate. Visible light having wavelengths from about 400 nm to 800 nm is able to quickly and efficiently heat silicon wafers from ambient temperature, e.g., about 20° C., to about 600° C. because silicon absorbs light within this range. In contrast, radiant, including infrared radiant, heating may ineffectively heat silicon at temperatures up to about 400° C. because silicon tends to be transparent to infrared at temperatures lower than about 400° C.. Additionally, radiant heaters that directly heat the topside of a wafer, as in many conventional semiconductor processes, can cause damage or other adverse effects to the topside films. Many “hot plate” heaters that rely on solid-to-solid thermal transference between the substrate and a heating platen, such as a pedestal with a heating coil, have relatively slow to heating and cooling rates, and provide non-uniform heating which may be caused by substrate warping and inconsistent contact with the heating platen. For example, it may take multiple minutes to heat some pedestals to a desired temperature, and from a first to a second higher temperature, as well as to cool the pedestal to a lower temperature.

The heater's plurality of LEDs may be arranged, electrically connected, and electrically controlled in various manners. Each LED may be configured to emit a visible blue light and/or a visible white light. In certain embodiments, white light (produced using a range of wavelengths in the visible portion of the electromagnetic (EM) spectrum) is used. In some semiconductor processing operations, white light can reduce or prevent unwanted thin film interference. For instance, some substrates have backside films that reflect different light wavelengths in various amounts, thereby creating an uneven and potentially inefficient heating. Using white light can reduce this unwanted reflection variation by averaging out the thin film interference over the broad visible spectrum provided by white light. In some instances, depending on the material on the back face of the substrate, it may be advantageous to use a visible non-white light, such as a blue light having a 450 nm wavelength, for example, in order to provide a single or narrow band of wavelength which may provide more efficient, powerful, and direct heating of some substrates that may absorb the narrow band wavelength better than white light.

Various types of LED may be employed. Examples include a chip on board (COB) LED or a surface mounted diode (SMD) LED. For SMD LEDs, the LED chip may be fused to a printed circuit board (PCB) that may have multiple electrical contacts allowing for the control of each diode on the chip. For example, a single SMD chip may have three diodes (e.g., red, blue, or green) that can be individually controllable to create different colors, for instance. SMD LED chips may range in size, such as 2.8×2.5 mm, 3.0×3.0 mm, 3.5×2.8 mm, 5.0×5.0 mm, and 5.6×3.0 mm. For COB LEDs, each chip can have more than three diodes, such as nine, 12, tens, hundreds or more, printed on the same PCB. COB LED chips typically have one circuit and two contacts regardless of the number of diodes, thereby providing a simple design and efficient single color application. The ability and performance of LEDs to heat the substrate may be measured by the watts of heat emitted by each LED; these watts of heat may directly contribute to heating the substrate.

In some embodiments, the pedestal is also configured to move vertically. This may include moving the pedestal such that a gap 1586 between a faceplate 1576 of the gas distribution unit 1510 and the substrate 1518 is capable of being in a range of 2 mm and 70 mm. As provided in more detail below, moving the pedestal vertically may enable active cooling of the substrate as well as rapid cycling time of processing operations, including flowing gas and purging, due to a low volume created between the gas distribution unit 1510 and the substrate 1518. This movement may also enable the creation of a small process volume between the substrate and the gas distribution unit which can result in a smaller purge and process volume and thus reduce purge and gas movement times and increase throughput.

The gas distribution unit 1510 is configured to flow process gases, which may include liquids and/or gases, such as a reactant, modifying molecules, converting molecules, or removal molecules, onto the substrate 1518 in the chamber interior 1514. As seen in FIG. 15, the gas distribution unit 1510 includes one or more fluid inlets 1570 that are fluidically connected to one or more gas sources 1572 and/or one or more vapor sources 1574. In some embodiments, the gas lines and mixing chamber may be heated to prevent unwanted condensation of the vapors and gases flowing within. These lines may be heated to at least about 40° C., at least about 80° C., at least about 90° C., at least about 120° C., at least about 130° C., or at least about 150° C.. The one or more vapor sources may include one or more sources of gas and/or liquid which is vaporized. The vaporizing may be a direct inject vaporizer, a flow over vaporizer, or both. The gas distribution unit 1510 also includes the faceplate 1576 that includes a plurality of through-holes 1578 that fluidically connect the gas distribution unit 1510 with the chamber interior 1514. These through-holes 1578 are fluidically connected to the one or more fluid inlets 1570 and also extend through a front surface 1577 of the faceplate 1576, with the front surface 1577 configured to face the substrate 1518. In some embodiments, the gas distribution unit 1510 may be considered a top plate and in some other embodiments, it may be considered a showerhead.

The through-holes 1578 may be configured in various ways in order to deliver uniform gas flow onto the substrate. In some embodiments, these through-holes may all have the same outer diameter, such as between about 0.03 inches and 0.05 inches, including about 0.04 inches (1.016 mm). These faceplate through-holes may also be arranged throughout the faceplate in order to create uniform flow out of the faceplate.

In some embodiments, the gas distribution unit 1510 may include a second unit heater 1582 that is configured to heat the faceplate 1576. This second unit heater 1582 may include one or more resistive heating elements, fluid conduits for flowing a heating fluid, or both. Using two heaters 1580 and 1582 in the gas distribution unit 1510 may enable various heat transfers within the gas distribution unit 1510. This may include using the first and/or second unit heaters 1580 and 1582 to heat the faceplate 1576 in order to provide a temperature-controlled chamber, as described above, in order to reduce or prevent unwanted condensation on elements of the gas distribution unit 1510.

The apparatus 1500 may also be configured to cool the substrate. This cooling may include flowing a cooling gas onto the substrate, moving the substrate close to the faceplate to allow heat transfer between the substrate and the faceplate, or both. Actively cooling the substrate enables more precise temperature control and faster transitions between temperatures which reduces processing time and improves throughput. In some embodiments, the first unit heater 1580 that flows the heat transfer fluid through fluid conduits may be used to cool the substrate 1518 by transferring heat away from the faceplate 1576 that is transferred from the substrate 1518. A substrate 1518 may therefore be cooled by positioning it in close proximity to the faceplate 1576, such as by a gap 1586 of less than or equal to 5 mm or 2 mm, such that the heat in the substrate 1518 is radiatively transferred to the faceplate 1576, and transferred away from the faceplate 1576 by the heat transfer fluid in the first unit heater 1580. The faceplate 1576 may therefore be considered a heat sink for the substrate 1518 in order to cool the substrate 1158.

In some embodiments, the apparatus 1500 may further include a cooling fluid source 1573 which may contain a cooling fluid (a gas or a liquid), and a cooler (not pictured) configured to cool the cooling fluid to a desired temperature, such as less than or equal to at least about 90° C., at least about 70° C., at least about 50° C., at least about 20° C., at least about 10° C., at least about 0° C., at least about −50° C., at least about −100° C., at least about −150° C., at least about −190° C., at least about −200° C., or at least about −250° C., for instance. The apparatus 1500 includes piping to deliver the cooling fluid to the one or more fluid inlets 1570, and the gas distribution unit 1510 which is configured to flow the cooling fluid onto the substrate. In some embodiments, the fluid may be in liquid state when it is flowed to the chamber 1502 and may turn to a vapor state when it reaches the chamber interior 1514, for example if the chamber interior 1514 is at a low pressure state, such as described above, e.g., between about 0.1 Torr and 10 Torr, or between about 0.1 Torr and 100 Torr, or between about 20 Torr and 200 Torr, for instance. The cooling fluid may be an inert element, such as nitrogen, argon, or helium. In some instances, the cooling fluid may include, or may only have, a non-inert element or mixture, such as hydrogen gas. In some embodiments, the flow rate of the cooling fluid into the chamber interior 1514 may be at least about 0.25 liters per minute, at least about 0.5 liters per minute, at least about 1 liters per minute, at least about 5 liters per minute, at least about 10 liters per minute, at least about 50 liters per minute, or at least about 100 liters per minute, for example. In certain embodiments, the apparatus may be configured to cool a substrate at one or more cooling rates, such as at least about 5° C./second, at least about 10° C./second, at least about 15° C./second, at least about 20° C./second, at least about 30° C./second, or at least about 40° C./second.

The apparatus 1500 may also include one or more additional non-contact sensors for detecting the temperature of the substrate. One such sensor may be a new pyrometer that is capable of detecting numerous temperature ranges of a silicon substrate. It is desirable to detect the temperature of substrates having different treatments, e.g., whether the silicon is doped or not doped, at different temperatures ranges at which processing operations may occur, such as under about 200° C., greater than about 200° C. and less than about 600° C., or above 600° C.. However, some pyrometers are not able to detect different substrates within these ranges. Some pyrometers measure the optical signals reflected or emitted by an object's surface to determine the object's temperature according to some calibration. However, many silicon wafers cannot be measured by these pyrometers because the silicon is optically transparent at various temperatures and with various treatments. For example, some pyrometers are capable of detecting emissions in a range of about 8-15 microns, but most silicon substrates under at least about 200° C. do not have an consistent emission signal in the range of about 8-15 microns and are therefore undetectable by some pyrometers when under about 200° C.

Lightly doped, or undoped, silicon substrates have an emission signal from approximately 0.95 to 1.1 microns when the substrates are at or below about 300° C., that doped silicon substrates have an emission signal between about 1 and 4 microns when the substrates are below about 200° C., that silicon substrates have an emission signal at approximately 1 micron when around room temperature, such as under about 100° C. including, for instance 20° C., and that silicon substrates have an emission signal of about 8 to 15 microns when at temperatures over about 600° C.. The new pyrometer is therefore configured to detect multiple emission ranges in order to detect multiple substrates, e.g., doped, low doped, or not doped, at various temperature ranges. This includes the configuration to detect emission ranges of about 0.95 microns to about 1.1 microns, about 1 micron, about 1 to about 4 microns, and/or about 8 to 15 microns. The new pyrometer is also configured to detect the temperature of a substrate at a shorter wavelength in order to differentiate the signal from the thermal noise of the chamber.

The new pyrometer may include an emitter configured to emit infrared signals and a detector configured to receive emissions. Referring to FIG. 15, the apparatus includes the new pyrometer 1588 having an emitter within the pyrometer 1588 and a detector 1590. The new pyrometer may be configured to emit signals on one side of the substrate, either the top or the bottom, and configured to receive signals on the other side of the substrate. For instance, the emitter may emit signals on the top of the substrate and the detector is under the substrate and receives signals emitted through and under the substrate. The apparatus may therefore have at least a first port 1592A on the top of the chamber 1502, such as the port 1592A through the center of the gas distribution unit 1510, and a second port 1592B through the pedestal 1504 and substrate heater 1522. The emitter in the pyrometer 1588 may be connected to one of the ports 1592A or 1592B via a fiberoptic connection, such as the first port 1592A as shown in FIG. 15, and the detector is optically connected to the other port, such as the second port 1592B in FIG. 15. The first port 1592A may include a port window 1594 to seal the first port 1592A from the chemistries within the chamber interior 1514. The second port 1592B is seen in FIG. 15 extending through the pedestal 1504 and the substrate heater such that the emitter's emissions can pass through the substrate, through the window 1550, into the second port 1592B and to the detector 1590 that may be positioned in the second port or optically connected to the second port through another fiberoptic connection (not shown). In some other embodiments, the emitter and the detector are flipped, such that the emitter emits through the second port 1592B and the detector detects through the first port 1592A.

The apparatus 100 may also include one or more optical sensors 1598 to detect one or more metrics of the visible light emitted by the LEDs. In some embodiments, these optical sensors may be one or more photodetectors configured to detect the light and/or light intensity of the light emitted by the LEDs of the substrate heater. In FIG. 15, a single optical sensor 1598 is shown as connected to the chamber interior 1514 via fiberoptic connection such that the optical sensor 1598 is able to detect light emitted by the substrate heater 1522. The optical sensor 1598, and additional optical sensors, can be positioned in various locations in the top and sides, for instance, of the chamber 1502 in order to detect the emitted light at various locations within the chamber 1502. As discussed below, this may enable the measurement and adjustment of the substrate heater, such as the adjustment of one or more independently controllable zones of the LEDs. In some embodiments, there may be a plurality of optical sensors 1598 arranged along a circle or multiple concentric circles in order to measure various regions of the LEDs throughout the chamber 1502. In some embodiments, the optical sensors may be positioned inside the chamber interior 1514.

In some embodiments, the apparatus may further be configured to generate a plasma and use the plasma for some processing in various embodiments. This may include having a plasma source configured to generate a plasma within the chamber interior, such as a capacitively coupled plasma (CCP), an inductively coupled plasma (ICP), an upper remote plasma, and a lower remote plasma.

The apparatuses described herein are not limited to ALE etching operations. These apparatuses may be used with any etching technique.

The pedestal may include reflective material on its internal surfaces that, during operation, reflects and directs the light emitted by the LEDs onto the backside of the substrate supported by the pedestal. In some such embodiments, the substrate heater may include such reflective material positioned on a top surface 1540, as shown in FIG. 15, of the PCB 1526 on which the plurality of LEDs 1524 is positioned. The reflective material may be comprised of aluminum, such as polished aluminum, stainless steel, aluminum alloys, nickel alloys, and other protective layers which can prevent oxidation of the metal and/or enhance the reflectivity at specific wavelengths, such as reaching greater than 99% reflectivity for specific wavelengths, and other durable reflective coatings. Additionally or alternatively, the pedestal 1504 may have a bowl 1546 in which the substrate heater 1522 is at least partially positioned. The bowl 1546 may have exposed internal surfaces 1548 of the pedestal sidewalls 1549 upon which the reflective material may be positioned. This reflective material increases the heating efficiency of the substrate heater and reduces the unwanted heating of the PCB 1526 and pedestal 1504 by advantageously directing light back onto the substrate that would have otherwise been absorbed by the PCB 1526 and the pedestal 1504.

In some embodiments, the substrate heater may also include a pedestal cooler that is thermally connected to the LEDs such that heat generated by the plurality of LEDs can be transferred from the LEDs to the pedestal cooler. This thermal connection is such that heat can be conducted from the plurality of LEDs to the pedestal cooler along one or more heat flow pathways between these components. In some instances, the pedestal cooler is in direct contact with one or more elements of the substrate heater, while in other instances other conductive elements, such as thermally conductive plates (e.g., that comprise a metal) are interposed between the substrate heater and the pedestal cooler. The substrate heater includes a pedestal cooler 1536 in direct contact with the bottom of the PCB 1526. Heat is configured to flow from the LEDs, to the PCB 1526, and to the pedestal cooler 1536. The pedestal cooler 1536 also includes a plurality of fluid conduits 138 through which a heat transfer fluid, such as water, is configured to flow in order to receive the heat and thus cool the LEDs in the substrate heater 1522. The fluid conduits 1538 may be connected to a reservoir and pump, not pictured, located outside the chamber. In some instances, the pedestal cooler may be configured to flow water that is cooled, such as between about 5° C. and 20° C.

As provided herein, it may be advantageous to actively heat the exterior surfaces of the processing chamber 1502. In some instances, it may similarly be advantageous to heat the exterior surfaces of the pedestal 1504 in order to prevent unwanted condensation and deposition on its external surfaces. The pedestal 1504 may further include a pedestal heater 1544 inside of the pedestal 1504 that is configured to heat the exterior surfaces of the pedestal 1504, including its sides 1542A and bottom 1542B. The pedestal heater 1544 may include one or more heating elements, such as one or more resistive heating elements and fluid conduits in which a heating fluid is configured to flow. In some instances, the pedestal cooler and the pedestal heater may both have fluid conduits that are fluidically connected to each other such that the same heat transfer fluid may flow in both the pedestal cooler and the pedestal heater. In these embodiments, the fluid may be heated to between 50° C. and 130° C. including about 90° C. and 120° C.

The pedestal may also include a window to protect the substrate heater, including the plurality of LEDs, from damage caused by exposure to the processing chemistries and pressures used during processing operations. As illustrated in FIG. 15, the window 1550 may be positioned above the substrate heater 1522 and may be sealed to the sidewall 1549 of the pedestal 1504 in order to create a plenum volume within the pedestal that is fluidically isolated from the chamber interior. This plenum volume may also be considered the inside of the bowl 1546. The window may be comprised of one or more materials that are optically transparent to the visible light emitted by LEDs, including light having wavelengths in the range of 400 nm to 800 nm. In some embodiments, this material may be quartz, sapphire, quartz with a sapphire coating, or calcium fluoride (CaF). The window may also not have any holes or openings within it. In some embodiments, the heater may have a thickness of 15 to 30 mm, including 20 mm and 25 mm.

With the window 1550 positioned above the substrate heater 1522, the window 1550 gets heated by the substrate heater 1522 which can affect the thermal environment around the substrate. Depending on the material or materials used for the window 1550, such as quartz, the window may retain heat and progressively retain more heat over the course of processing one or more substrates. This heat can get radiatively transferred to the substrate and therefore directly heat the substrate. In some instances, that the window can cause a temperature increase of between 50° C. and 80° C. above the heater temperature. This heat may also create a temperature gradient through the thickness, or in the vertical direction, of the window. In some instances, the top surface is 30° C. hotter than the bottom surface. It may therefore be advantageous to adjust and configure the chamber to account for and reduce the thermal effects of the window. As described in more detail below, this may include detecting the substrate's temperature and adjusting the substrate heater to account for the heat retained by the window.

In some embodiments, the apparatuses described herein may include a controller that is configured to control various aspects of the apparatus in order to perform the techniques described herein. Apparatus 1500 includes a controller 1531 (which may include one or more physical or logical controllers) that is communicatively connected with and that controls some or all of the operations of a processing chamber. The system controller 1531 may include one or more memory devices 1533 and one or more processors 1535. In some embodiments, the apparatus includes a switching system for controlling flow rates and durations, the substrate heating unit, the substrate cooling unit, the loading and unloading of a substrate in the chamber, the thermal floating of the substrate, and the process gas unit, for instance, when disclosed embodiments are performed. In some embodiments, the apparatus may have a switching time of up to about 500 ms, or up to about 750 ms. Switching time may depend on the flow chemistry, recipe chosen, reactor architecture, and other factors.

In some implementations, the controller 1531 is part of an apparatus or a system, which may be part of the above-described examples. Such systems or apparatuses can include semiconductor processing equipment, including a processing tool or tools, chamber or chambers, a platform or platforms for processing, and/or specific processing components (a gas flow system, a substrate heating unit, a substrate cooling unit, etc.). These systems may be integrated with electronics for controlling their operation before, during, and after processing of a semiconductor wafer or substrate. The electronics may be referred to as the “controller,” which may control various components or subparts of the system or systems. The controller 1531, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller 1531 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing operations during the fabrication of one or more layers, materials, metals, oxides, silicon, silicon dioxide, surfaces, circuits, and/or dies of a wafer.

The controller 1531, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing operations to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 1531 receives instructions in the form of data, which specify parameters for each of the processing operations to be performed during one or more operations. It should be understood that the parameters may be specific to the type of process to be performed and the type of tool that the controller is configured to interface with or control. Thus as described above, the controller 1531 may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

As noted above, depending on the process operation or operations to be performed by the apparatus, the controller 1531 might communicate with one or more of other apparatus circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

As also stated above, the controller is configured to perform any technique described above. This may include causing a substrate transfer robot to position the substrate in the chamber on the plurality of substrate supports causing power to be delivered to the LEDs so that they emit the visible light having wavelengths between 400 nm and 800 nm to heat the substrate to a first temperature, such as between 100° C. and 600° C., and causing etchant gases to flow into the chamber and etch the substrate. This may also include cooling, while the substrate is supported by only the plurality of substrate supports, the substrate by flowing the cooling gas onto the substrate, and/or moving the pedestal vertically so that the substrate is offset from a faceplate of a gas distribution unit by a first nonzero distance, and thereby causing heat to transfer from the substrate to the faceplate through noncontact radiation.

Yet other apparatuses useful for the practice of the methods described herein are described in U.S. Pat. No. 11,488,831; Int'l. Pat. Pub. No. WO 2021/202171; U.S. Patent Publication No. 2022/0356585 and Int'l. Pat. Pub. No. WO 2023/205591, each of which is incorporated herein by reference in its entirety.

### Further Implementations

The apparatus and processes described herein may be used in conjunction with lithographic patterning tools or processes, for example, for the fabrication or manufacture of semiconductor devices, displays, LEDs, photovoltaic panels, and the like. Typically, though not necessarily, such apparatus and processes will be used or conducted together in a common fabrication facility. Lithographic patterning of a film typically comprises some or all of the following steps, each step enabled with a number of possible tools: (1) application of photoresist on a work piece, i.e., a substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or work piece by using a dry or plasma-assisted etching tool; and (6) removing the resist using a tool such as an RF or microwave plasma resist stripper.

### Conclusion

Although omitted for conciseness, embodiments of the system and/or method can include every combination and permutation of the various system components and the various method processes, wherein one or more instances of the method and/or processes described herein can be performed asynchronously (e.g., sequentially), concurrently (e.g., in parallel), or in any other suitable order by and/or using one or more instances of the systems, elements, and/or entities described herein.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

1. A method for forming a patterning structure, the method comprising:
providing a substrate;
depositing an underlayer having a top surface on the substrate;
oxidatively treating the top surface of the underlayer to form a stabilized underlayer;
forming a film of a radiation-sensitive imaging layer comprising a metal oxide-containing photoresist on the stabilized underlayer;
exposing the film to extreme ultraviolet radiation to make a film comprising exposed regions and unexposed regions and to activate the stabilized underlayer to generate reactive species, wherein the reactive species generated in the stabilized underlayer preferentially interact with the exposed regions to form exposed cross-linked regions;
performing a post-exposure bake and
developing the film comprising exposed cross-linked regions and unexposed regions; and
whereby the stabilized underlayer is oxidative age-resistant and provides reduced dose to size.

2. The method of claim 1, wherein oxidatively treating the underlayer comprises a dry treatment, heating, a wet treatment, an oxygen plasma treatment or a combination thereof.

3. The method of claim 2, wherein the heating is performed at a temperature of about 50° C. to about 180° C. while exposing the underlayer to an oxygen-containing gas.

4. The method of claim 2, wherein the dry treatment comprises a treatment with nitrous oxide gas, ozone gas, water vapor, hydrogen peroxide vapor, or a combination thereof.

5. The method of claim 2, wherein the wet treatment comprises treatment with water, treatment with hydrogen peroxide in water or treatment with ozone in water.

6. The method of claim 1, wherein depositing the underlayer on the substrate and oxidatively treating the top surface of the underlayer are performed simultaneously.

7. The method of claim 1, wherein oxidatively treating the top surface of the underlayer and forming a film of a radiation-sensitive imaging layer on the underlayer are performed simultaneously.

8. The method of claim 1, wherein the underlayer comprises a carbon-containing underlayer, a silicon-containing underlayer, a carbon-containing doped film, or an amorphous carbon underlayer.

9. (canceled)

10. The method of claim 8, wherein the carbon-containing doped film satisfies at least one of the following conditions:
(a) the carbon-containing doped film comprises hydrogenated carbon doped with oxygen, silicon, nitrogen, tungsten, boron, iodine, chlorine or a combination thereof; and
(b) the carbon-containing doped film is doped with a halogen, a metal, an organometallic complex, hydrogen, oxygen, or a combination thereof.

11. (canceled)

12. (canceled)

13. The method of claim 10, wherein the carbon-containing doped film is doped with organometallic complex comprising oxidizable metal-carbon bonds.

14. (canceled)

15. A method for preparing a substrate for extreme ultraviolet photolithography, the method comprising:
providing a substrate;
depositing an underlayer having a top surface on the substrate; and oxidatively treating the top surface of the underlayer to form a stabilized underlayer, whereby the stabilized underlayer is oxidative age-resistant and provides reduced dose to size.

16. The method of claim 15, wherein oxidatively treating the underlayer comprises a dry treatment, heating, a wet treatment, an oxygen plasma treatment or a combination thereof.

17. The method of claim 16, wherein the heating is performed at a temperature of about 50° C. to about 180° C. while exposing the underlayer to an oxygen-containing gas.

18. The method of claim 16, wherein the dry treatment comprises a treatment with nitrous oxide gas, ozone gas, water vapor, hydrogen peroxide vapor or a combination thereof.

19. The method of claim 16, wherein the wet treatment comprises treatment with water, treatment with hydrogen peroxide in water or treatment with ozone in water.

20. The method of claim 15, wherein depositing the underlayer on the substrate and oxidatively treating the top surface of the underlayer are performed simultaneously.

21. The method of claim 15, wherein the underlayer comprises a carbon-containing underlayer, a carbon-containing doped film, an amorphous carbon underlayer, or a silicon-containing underlayer.

22. (canceled)

23. The method of claim 21, wherein the carbon-containing doped film satisfies at least one of the following conditions:
(a) the carbon-containing doped film comprises hydrogenated carbon doped with oxygen, silicon, nitrogen, tungsten, boron, iodine, chlorine or a combination thereof; and
(b) The carbon-containing doped film is doped with a halogen, a metal, an organometallic complex, hydrogen, oxygen, or a combination thereof.

24. (canceled)

25. (canceled)

26. The method of claim 23, wherein the carbon-containing doped film is doped with the organometallic complex comprising oxidizable metal-carbon bonds.

27. (canceled)

28. An apparatus for treating an underlayer, the apparatus comprising:
a process chamber comprising a substrate support;
a process gas source connected with the process chamber and flow-control hardware;
an underlayer oxidative treatment module operatively connected to the process chamber; and
an underlayer oxidative treatment module controller having a processor and a memory, wherein the processer and the memory are communicatively connected with one another, the processor is at least operatively connected with the flow-control hardware, and the memory stores computer-executable instructions for
causing oxidative treatment of the underlayer to form a stabilized underlayer, wherein the stabilized underlayer is oxidative age-resistant and provides reduced dose to size.

29. The apparatus of claim 28, wherein the underlayer oxidative treatment module comprises an ampoule assembly connected to a vaporizer and an ozone generator; a plasma generator; a heater; or a combination thereof.
